(19) United States
(12) Patent Application Publication
(10) Pub. No.: US 2025/0259872 A1
(43) Pub. Date: Aug. 14, 2025

(54) SWAPPER FOR A CLUSTER TOOL

(71) Applicant: Applied Materials, Inc., Santa Clara, CA (US)

(72) Inventors: Rajkumar THANU, Santa Clara, CA (US); Jeffrey C. HUDGENS, San Francisco, CA (US)

(21) Appl. No.: 19/036,301

(22) Filed: Jan. 24, 2025

Related U.S. Application Data
(60) Provisional application No. 63/552,628, filed on Feb. 12, 2024.

(51) Int. Cl. H01L 21/677; B65G 49/07; H01L 21/67; H01L 21/687

(52) U.S. Cl. CPC H01L 21/67706; B65G 49/07; H01L 21/67201; H01L 21/68707; B65G 2201/0297

(57) ABSTRACT

In one embodiment, a swapper for a cluster tool includes: a base, a pulley system, and first and second arms. The base may include an interior chamber. The base may be rotatable about a central axis. The pulley system may be at least partially disposed in the interior chamber. The pulley system may include a multi-level central pulley, first and second elbow pulleys, and first and second belts. The base may be rotatable relative to the multi-level central pulley. The first and second elbow pulleys may be rotatable about respective first and second elbow axes. Each belt may loop around a respective level of the multi-level central pulley and the corresponding elbow pulley. Each arm may be rotationally coupled to the respective elbow pulley such that rotation of the elbow pulley rotates the arm about the corresponding elbow axis.

### CROSS-REFERENCE TO RELATED APPLICATIONS

This application claims priority to and the benefit of U.S. Provisional Patent Application No. 63/552,628 entitled “A SWAPPER FOR A CLUSTER TOOL” filed Feb. 12, 2024. The aforementioned application is incorporated by reference herein.

### BACKGROUND

### Field

Embodiments of the present disclosure generally relate to the linear transport of substrates, such as semiconductor substrates, in a cluster tool.

### Description of the Related Art

Cluster tools are used in the manufacturing of semiconductor devices on substrates. Cluster tools have robotic mechanisms that are used to convey substrates between different chambers within the cluster tool. A substrate is placed in a load lock of the cluster tool and then may be transferred between multiple robotic mechanisms before being placed into a processing chamber that deposits or otherwise forms a layer or feature on the surface of the substrate. Additionally, these robotic mechanisms are operated by different motors.

There is a need in the art for an improved swapper robot to directly transfer a substrate from a load lock to a processing chamber.

### SUMMARY

In one embodiment, a swapper for a cluster tool comprises a base, a pulley system, a first arm, and a second arm. The base including an interior chamber, wherein the base is rotatable about a central axis. The pulley system is at least partially disposed in the interior chamber. The pulley system includes a multi-level central pulley, a first elbow pulley, a second elbow pulley, a first belt, and a second belt. The base is rotatable relative to the multi-level central pulley. The first elbow pulley rotatable about a first elbow axis. The second elbow pulley rotatable about a second elbow axis. The first belt looping around a first level of the multi-level central pulley and the first elbow pulley. The second belt looping around a second level of the multi-level central pulley and the second elbow pulley. The first arm is rotationally coupled to the first elbow pulley such that rotation of the first elbow pulley rotates the first arm about the first elbow axis. The second arm is rotationally coupled to the second elbow pulley such that rotation of the second elbow pulley rotates the second arm about the second elbow axis.

In one embodiment, a swapper for a cluster tool comprises a base, a pulley system, a first arm, and a second arm. The base including an interior chamber, wherein the base is rotatable about a central axis. The pulley system is at least partially disposed in the interior chamber. The pulley system includes a multi-level central pulley, a multi-level first elbow pulley, a multi-level second elbow pulley, a first band, a second band, a third band, and a fourth band. The base is rotatable relative to the multi-level central pulley. The multi-level first elbow pulley is rotatable about a first elbow axis. The multi-level second elbow pulley is rotatable about a second elbow axis. A first end of the first band is anchored to a first level of the multi-level central pulley and a second end of the first band is anchored to a first level of the first multi-level elbow pulley. A first end of the second band is anchored to the first level of the multi-level central pulley and a second end of the second band is anchored to a first level of the second multi-level elbow pulley. A first end of the third band is anchored to a second level of the multi-level central pulley and a second end of the third band is anchored to a second level of the first multi-level elbow pulley. A first end of the fourth band is anchored to the second level of the multi-level central pulley and a second end of the fourth band is anchored to a second level of the second multi-level elbow pulley. The first arm is rotationally coupled to the first multi-leveled elbow pulley such that rotation of the first multi-leveled elbow pulley rotates the first arm about the first elbow axis. The second arm is rotationally coupled to the second multi-leveled elbow pulley such that rotation of the second multi-leveled elbow pulley rotates the second arm about the second elbow axis.

In one embodiment, a swapper assembly for a cluster tool comprises a housing and a swapper. The housing includes a first opening and a second opening. The swapper includes a base, a first arm, and a second arm. The base is rotatable relative to the housing about a central axis. The first arm is rotationally coupled to the base, wherein the first arm rotates relative to the base about a first elbow axis from a first retracted position to a first extended position, wherein the first arm is partially disposed in the first opening in the first extended position and the first elbow axis is disposed in the housing in the first extended position. The second arm is rotationally coupled to the base, wherein the second arm rotates relative to the base about a second elbow axis from a second retracted position to a second extended position, wherein the second arm is partially disposed in the second opening in the second extended position and the second elbow axis is disposed in the housing in the second extended position.

In one embodiment, a swapper for a cluster tool comprises a base, a first base pulley system, a second base pulley system, a first link, a second link, a first arm, and a second arm. The base including an interior chamber, wherein the base is rotatable about a central axis. The first base pulley system is at least partially disposed in the interior chamber of the base. The first base pulley system includes a first multi-level central pulley, a multi-level first elbow pulley, a multi-level second elbow pulley, a first band, a second band, a third band, and a fourth band. The base is rotatable relative to the first multi-level central pulley. The multi-level first elbow pulley is rotatable about a first elbow axis. The multi-level second elbow pulley is rotatable about a second elbow axis. A first end of the first band is anchored to a first level of the first multi-level central pulley and a second end of the first band is anchored to a first level of the first multi-level elbow pulley. A first end of the second band is anchored to a second level of the first multi-level central pulley and a second end of the second band is anchored to a second level of the first multi-level elbow pulley, wherein the first band crosses above the second band. A first end of the third band is anchored to the first level of the first multi-level central pulley and a second end of the third band is anchored to a first level of the second multi-level elbow pulley. A first end of the fourth band is anchored to the second level of the first multi-level central pulley and a second end of the fourth band is anchored to a second level of the second multi-level elbow pulley, wherein the third band crosses above the fourth band. The second base pulley system is at least partially disposed in the interior chamber of the base. The second base pulley system includes a second multi-level central pulley, a first pulley, a second pulley, a first belt, and a second belt. The second multi-level central pulley is rotatable relative to the first multi-level central pulley about the central axis. The first pulley is rotatable about the first elbow axis. The second pulley is rotatable about the second elbow axis. The first belt is looped around a first level of the second multi-level central pulley and the first pulley. The second belt is looped around a second level of the second multi-level central pulley and the second pulley. The first link is rotatably attached to the first elbow pulley and including a first link pulley system at least partially disposed in a first chamber of the first link. The first link pulley system comprises a first link pulley, a second link pulley, a first belt. The first link pulley is rotationally coupled to the first pulley such that rotation of the first pulley rotates the first link pulley about the first elbow axis. The second link pulley is rotatable about a first arm axis. The first belt is looped around the first link pulley and the second link pulley. The second link attached to the second elbow pulley including a second link pulley system at least partially disposed in a second chamber of the second link. The second link pulley system comprises a third link pulley, a fourth link pulley, and a second belt. The third link pulley is rotationally coupled to the second pulley such that rotation of the second pulley rotates the second link pulley about the second elbow axis. The fourth link pulley is rotatable about a second arm axis. The second belt looped around the third link pulley and the fourth link pulley. The first arm is rotationally coupled to the second link pulley such that rotation of the second link pulley rotates the first arm about the first arm axis. The second arm rotationally coupled to the fourth link pulley such that rotation of the fourth link pulley rotates the second arm about the second arm axis.

In one embodiment, a method of operating a swapper includes moving a first arm of the swapper from a first extended position to a first partially retracted position by rotating a base of a swapper about a central axis in a first direction while rotating a first link coupled to the base in the first direction and rotating the first arm coupled to the first link in a second direction. The method further includes moving the first arm of the swapper to a second partially retracted position from the first partially retracted position by rotating the base in the first direction while rotating the first link in the first direction and rotating the first arm in the second direction. The method further includes moving the first arm of the swapper to a retracted position from the second partially retracted position by rotating the base in the second direction while rotation the first link in the second direction and rotating the first arm in the second direction.

In one embodiment, an in-line tensioner comprises a block and a biasing element. The block includes a channel, a first block opening, and a second block opening. The biasing element is disposable in the channel. The biasing element includes a first portion including a slot, a second portion including a block fastener opening, and a third portion disposed between the first portion and the second portion. The third portion includes a plurality of spring slots. The third portion is configured to bias the first portion towards the second portion.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments of the disclosure and are therefore not to be considered limiting of its scope, as the disclosure may admit to other equally effective embodiments.

FIG. 1A illustrates a schematic plan view of an exemplary cluster tool, according to embodiments described herein.

FIG. 1B is a schematic partial cross-sectional view of a swapper assembly, according to embodiments described herein.

FIG. 1C is a partial exploded view of a swapper, according to embodiments herein.

FIG. 2A illustrates a schematic plan view of an exemplary cluster tool, according to embodiments described herein.

FIG. 2B is a schematic partial cross-sectional view of a swapper assembly, according to embodiments described herein.

FIG. 2C is a partial exploded view of a swapper, according to embodiments herein.

FIG. 3A illustrates a schematic plan view of an exemplary cluster tool, according to embodiments described herein.

FIG. 3B illustrates a partial schematic plan view of the exemplary cluster tool shown in FIG. 3A showing the arms of the swapper in an extended position, according to embodiments described herein.

FIG. 3C illustrates a partial schematic plan view of the exemplary cluster tool shown in FIG. 3A showing the arms of the swapper in a partially retracted position, according to embodiments described herein.

FIG. 3D illustrates a partial schematic plan view of the exemplary cluster tool shown in FIG. 3A showing the arms of the swapper in a retracted position, according to embodiments described herein.

FIG. 3E illustrates a partial schematic plan view of the exemplary cluster tool shown in FIG. 3A showing the arms of the swapper in a partially extended position, according to embodiments described herein.

FIG. 3F illustrates a partial schematic plan view of the exemplary cluster tool shown in FIG. 3A showing the arms of the swapper in an extended position, according to embodiments described herein.

FIG. 4A illustrates a schematic plan view of an exemplary cluster tool, according to embodiments described herein.

FIG. 4B is a partial exploded view of a swapper, according to embodiments herein.

FIG. 4C illustrates a partial schematic plan view of the exemplary cluster tool shown in FIG. 4A showing the arms of the swapper in a first partially retracted position, according to embodiments described herein.

FIG. 4D illustrates a partial schematic plan view of the exemplary cluster tool shown in FIG. 4A showing the arms of the swapper in a second partially retracted position, according to embodiments described herein.

FIG. 4E illustrates a partial schematic plan view of the exemplary cluster tool shown in FIG. 4A showing the arms of the swapper in a retracted position, according to embodiments described herein.

FIG. 4F illustrates a partial schematic plan view of the exemplary cluster tool shown in FIG. 4A showing the arms of the swapper in a first partially extended position, according to embodiments described herein.

FIG. 4G illustrates a partial schematic plan view of the exemplary cluster tool shown in FIG. 4A showing the arms of the swapper in a second partially extended position, according to embodiments described herein.

FIG. 4H illustrates a partial schematic plan view of the exemplary cluster tool shown in FIG. 4A showing the arms of the swapper in an extended position, according to embodiments described herein.

FIG. 5 illustrates a partial exploded view of a belt system to show an exemplary in-line tensioner, according to embodiments described herein.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure generally provides an apparatus and method for processing substrates using a multi-chamber processing system (e.g., a cluster tool) adapted to process substrates. A cluster tool is a system comprising multiple chambers which perform various functions in the electronic device fabrication process. The cluster tool includes at least two swapping mechanisms operated by the same motor assembly to transfer substrates between two chambers within the cluster tool.

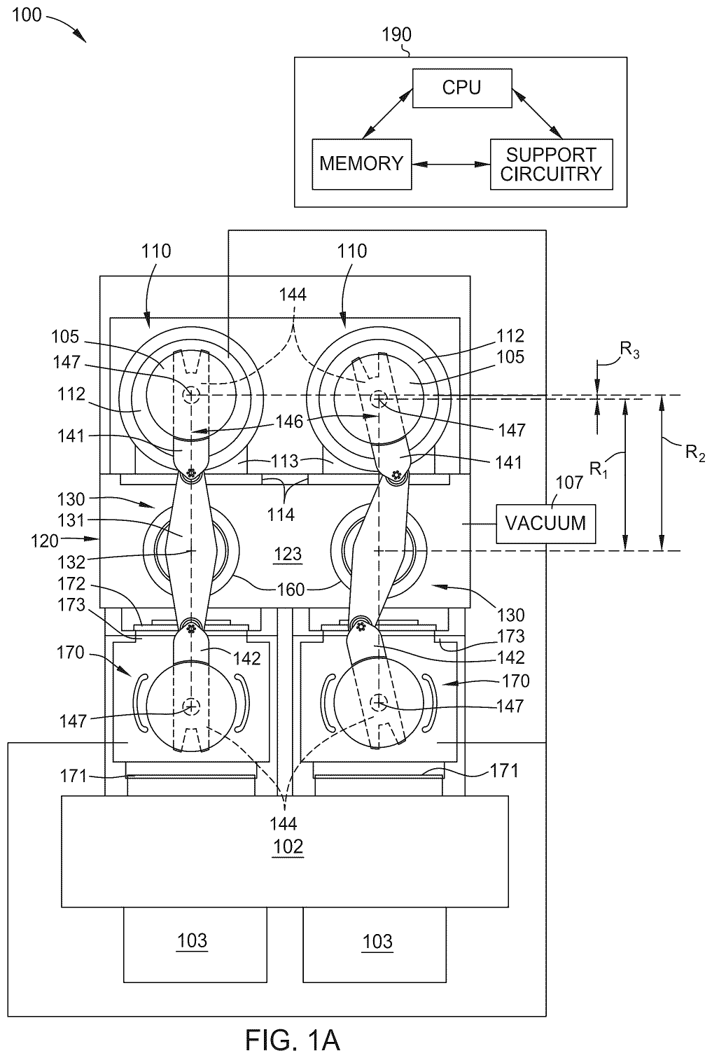

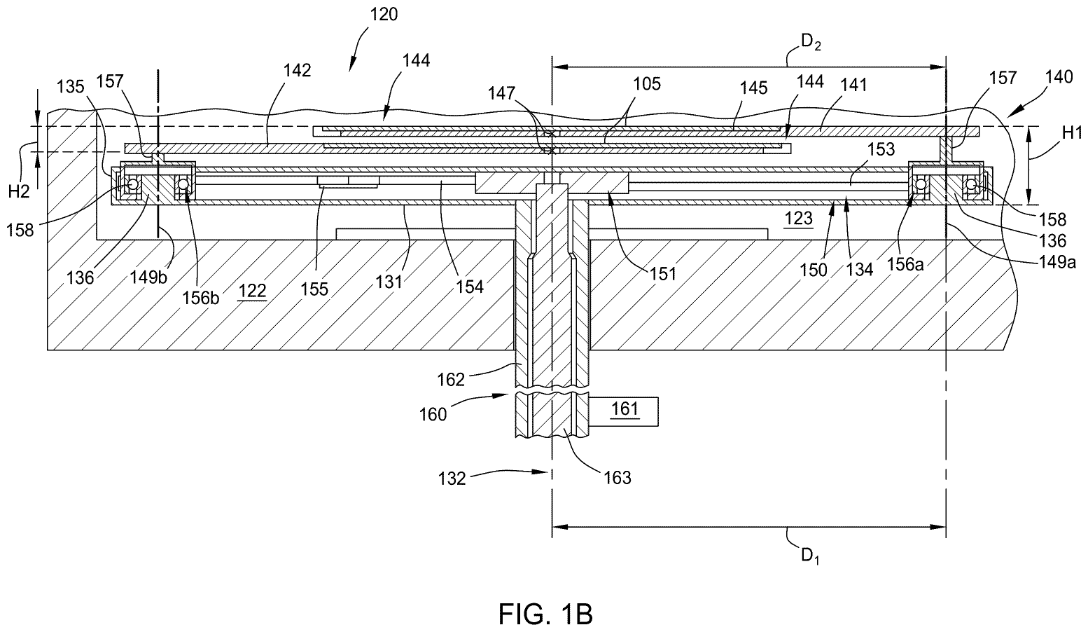

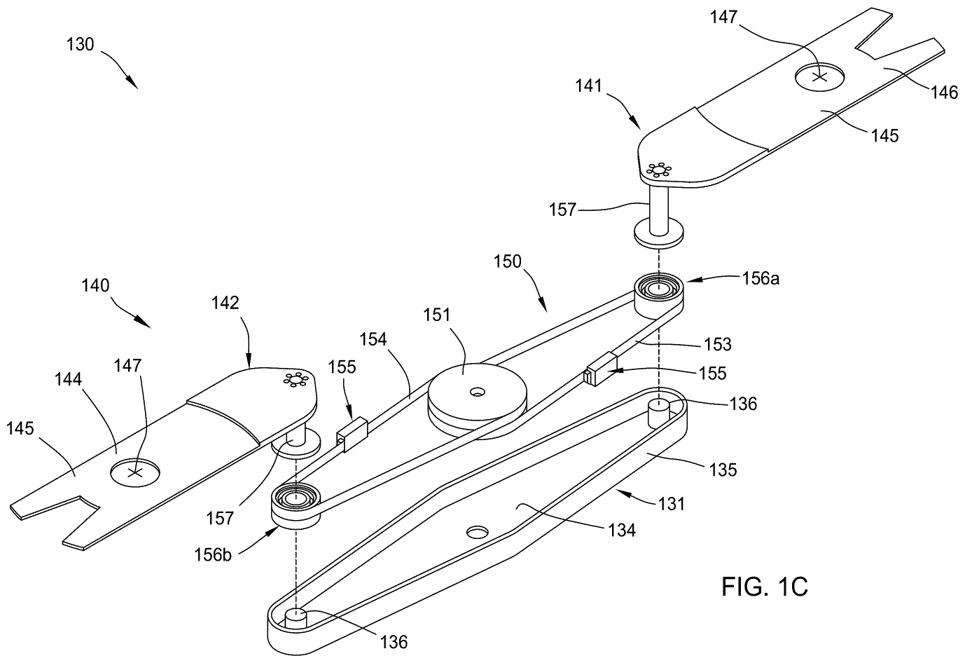

FIG. 1A illustrates a schematic plan view of a cluster tool 100. The cluster tool 100 includes a factory interface 102, two substrate processing chambers 110, a substrate swapper assembly 120, two load locks 170, and a controller 190. The load locks 170 and processing chambers 110 are in pairs, with each pair having one load lock 170 opposing a corresponding processing chamber 110. The substrate swapper assembly 120 is located between the processing chambers 110 and the load locks 170. The substrate swapper assembly 120 includes a swapper 130 for each pair of the processing chambers 110 and load locks 170. Each swapper 130 is used to swap the substrates 105 between the processing chamber 110 and load lock 170. The cluster tool 100 may also include a vacuum assembly 107 that is used to create and/or maintain a pressure within the cluster tool 100, such as the pressure within each processing chamber 110, the swapper assembly 120, and each load lock 170.

The factory interface 102 may be coupled to one or more front opening unified pods (FOUPs) 103. FOUPs 103 may each be a container having a stationary cassette therein for holding multiple substrates. FOUPs 103 may each have a front opening interface configured to be used with factory interface 102. Factory interface 102 may have a buffer chamber (not shown) and one or more robot assemblies (not shown) configured to transfer substrates via linear, rotational, and/or vertical movement between FOUPs 103 and the load locks 170.

The processing chambers 110 include a substrate support 112 (e.g., pedestal, platen) and a processing kit and source assembly configured to process the substrate 105 within the processing chamber 110. The processing chambers 110 may perform any number of processes such as preclean, PVD, CVD, ALD, decoupled plasma nitridation (DPN), rapid thermal processing (RTP), and etching. In one embodiment, the processing sequence is adapted to form a high-K capacitor structure, where processing chambers 110 may be a DPN chamber, a CVD chamber capable of depositing poly-silicon, and/or a MCVD chamber capable of depositing titanium, tungsten, tantalum, platinum, or ruthenium. The substrate support 112 may include one or more lift pins to lift and lower the substrate 105 relative to the substrate support 112, such as using the lift pins to transfer the substrate 105 to or from the swapper 130. In some embodiments, a slit valve 114 is located between the processing chamber 110 and the swapper assembly 120. When the slit valve 114 is in an open position, the swapper 130 is allowed to enter a tunnel 113 of the processing chamber 110. When the slit valve 114 is in the closed position, the processing chamber 110 is isolated from the swapper assembly 120. In some embodiments, the slit valve 114 is omitted.

Each load lock 170 may have a first slit valve 171 and a second slit valve 172. When the first slit valve 171 is open, a substrate 105 can be transferred from the factory interface 102 and to support members, such as lift pins, positioned in the load lock 170. When the first slit valve 171 is closed, the interior of the load lock 170 is isolated from the factory interface 102. Thus, the load locks 170 provide a vacuum interface between the factory interface 102 (e.g., front-end environment) and the remainder the cluster tool 100. When the second slit valve 172 is open, the swapper 130 is allowed to enter an opening 173 in the load lock 170 where the substrate 105 is then transferred to the swapper 130. The second slit valve 172 may be closed to block the opening 173. When the second slit valve 172 is closed, the interior of the load lock 170 is isolated from the swapper assembly 120 and the processing chambers 110. In some embodiments, there is only one load lock 170 that is configured to receive each swapper 130.

FIGS. 1A and 1B illustrate the swapper assembly 120, with FIG. 1B showing a schematic partial cross-sectional view of the swapper assembly 120. The swapper assembly 120 additionally includes a housing 122 and one or more motor assemblies 160. The housing 122 defines an internal swapper chamber 123. The swappers 130 are disposed in the swapper chamber 123, and the substrates 105 pass through the swapper chamber 123 between the load locks 170 and the processing chamber 110. Each swapper 130 is operated by a motor assembly 160 that is configured to move the swapper 130 between a retracted position and an extended position. In some embodiments, a wall of the housing 122 bifurcates the swapper chamber 123 such that each swapper 130 is isolated from the other.

Each swapper 130 includes a base 131, an arm assembly 140, and a pulley system 150. The base 131 includes an interior chamber 134 partially defined by the walls 135 of the base 131. The pulley system 150 is at least partially disposed within the interior chamber 134 of the base 131. The arm assembly 140 is supported by the base 131. The base 131 may be connected to a first shaft 162 of the motor assembly 160. A motor 161 of the motor assembly 160 rotates the first shaft 162 about a central axis 132 of the swapper 130, thereby rotating the base 131 about the central axis 132. In some embodiments, one or more seals may be disposed around the first shaft 162 to seal the swapper chamber 123 from the outside environment while facilitating the rotation of the base 131 relative to the housing 122.

The arm assembly 140 includes a first arm 141 (e.g., left arm) and a second arm 142 (e.g., right arm) that are rotated by the pulley system 150. The arms 141, 142 are moveable to extended positions where each arm 141, 142 is located within either the load lock 170 or the processing chamber 110 to convey a substrate 105 disposed on the arm 141, 142. FIG. 1A shows the arms 141, 142 of the swapper 130 on the right-hand side of the figure in a first extended position while the arms 141, 142 of the swapper 130 on the left-hand side of the figure are shown in a second extended position. As will be explained below, the difference in the first extended position and the second extended position allows for the swapper 130 to center the substrate 105 within the processing chamber 110. FIG. 1A shows the first arm 141 positioned within the processing chamber 110 above the substrate support 112 while the second arm 142 is shown positioned within the load lock 170. The arms 141, 142 are moved to swap positions, such that the first arm 141 is moved to into the load lock 170 while the second arm 142 is moved into the processing chamber 110. The arms 141, 142 may also be moved to a retracted position (FIG. 1B) where the arms 141, 142 overlap one another. The arms 141, 142 may be retracted while the arms 141, 142 are swapped between the load lock 170 and the processing chamber 110. The arms 141, 142 may also be retracted while a substrate 105, placed into the processing chamber 110, is processed.

The arms 141, 142 (e.g., end effectors) each include a support 144 with a support surface 145 as shown in FIG. 1C. As shown in FIG. 1A, the support 144 may have a fork shape or other desirable shape to support the substrate 105. The substrate 105 is placed into engagement with the support surface 145 of the support 144. The support 144 carries the substrate 105 disposed thereon as the swapper 130 moves the substrate 105 between the load lock 170 and the processing chamber 110. As shown in FIG. 1B, the support 144 of the first arm 141 and second arm 142 are located at different heights such that one arm can pass underneath the other arm without the substrate 105 on the lower arm contacting the upper arm. As shown, the first arm 141 is located at a height above the base 131 that is lower than the second arm 142. A clearance is present between the support surface 145 of the support 144 of the first arm 141 and the underside of the second arm 142. This clearance is sized to allow the substrate 105 to pass underneath the second arm 142 without contacting the second arm 142.

As shown in FIG. 1A, the base 131 partially extends into the opening 173 in the load lock 170 and partially extends into the tunnel 113 of the processing chamber 110. As shown in FIG. 1B, the swapper 130 has a first height H1 that extends from the underside of the base 131 to the upper side of the second arm 142. This first height H1 is less than the height of the opening of the tunnel 113 of the processing chamber 110 and the height of the opening 173 in the load lock 170. In other words, the swapper 130 is sized to allow the base 131 and arm assembly 140 to enter the opening 173 and tunnel 113 without contact. A second height H2 is shown extending from the underside of the second arm 142 to the top surface of the first arm 141. In some embodiments, the tunnel 113 may include an opening formed in the housing 122 of the swapper assembly 120. Additionally, the opening 173 may include an opening formed in the housing 122 of the swapper assembly 120. In other words, the swapper assembly 120 may have a first opening in the housing 122 aligned with the tunnel 113 and a second opening in the housing 122 aligned with the opening 173.

The opening 173 and the tunnel 113 each have a height that exceeds first height H1 such that the base 131 and arms 141, 142 may pass through without contacting a surface of the opening 173 or tunnel 113. For example, the opening 173 and tunnel 113 may have a height that is at least 50 mm, such as 55 mm, such as 60 mm, such as 70 mm. In some embodiments, the base 131 may have a height between 20 mm and 30 mm, such as about 20 mm, such as about 25 mm, such about 30 mm. The distance from the upper surface of the base 131 to the upper surface of the first arm 141 may also be between 20 mm and 30 mm, such as about 20 mm, such as about 25 mm, such about 30 mm.

As shown in FIGS. 1A and 1B, the support 144 of each arm 141, 142 has center point 147 that may or may not be located on the support surface 145 depending on the shape of the support 144. The center point 147 is the location of the support 144 that will be aligned with the center of the substrate 105 if the substrate 105 is properly centered on the support surface 145.

FIG. 1A shows a substrate 105 placed on the support 144 of each arm 141, 142. A portion of each arm 141, 142 is shown in dashed to illustrate that the substrate 105 is supported on the corresponding arm 141, 142. The center point 147 of each arm 141, 142 will follow the trajectory 146 as the motor assembly 160 operates the swapper 130 to move the arms 141, 142. As shown in FIG. 1A, the trajectory 146 (shown as a line) is a substantially linear path that extends from the center point of the substrate support 112, over the central axis 132 of the swapper 130, to a center point of the load lock 170. In other words, the center point 147 moves linearly as the first arm 141 and second arm 142 swap positions. The substrate 105 disposed on the support 144 of each arm 141, 142 similarly moves in a linear fashion. Thus, the swapper 130 is used to move the substrates 105 in a linear trajectory between the load lock 170 and processing chamber 110, and vice versa. The arms 141, 142 move the substrate 105 disposed thereon along parallel linear trajectories that are separated by a distance since each arm 141, 142 is located at a different height. And, as shown in FIG. 1A, each pair of processing chambers 110 and load locks 170 are positioned opposing each other across the swapper assembly 120 such that the linear trajectory of the substrates 105 moved by one swapper 130 is parallel to the linear trajectory of the substrates 105 moved by the other swapper 130.

FIGS. 1B and 1C show the pulley system 150. FIG. 1C illustrates a partial exploded view of the swapper 130 to show the interconnection of the pulley system 150 with other select components of the swapper 130. The pulley system 150 includes a central pulley 151, a first belt 153, a second belt 154, a first elbow pulley 156a, and a second elbow pulley 156b. The first arm 141 is attached to the first elbow pulley 156a and the second arm 142 is attached to the second elbow pulley 156b. In some embodiments, the central pulley 151 is in a fixed position. For example, the central pulley 151 may be fixed on a second shaft 163 that extends into the interior chamber 134 through an opening in the walls 135 of the base 131 and through an opening of the first shaft 162. The motor assembly 160 may include one or more bearing elements to facilitate the rotation of the base 131 and the first shaft 162 relative to the second shaft 163.

The central pulley 151 is shown as a multi-level pulley, in that the central pulley 151 accommodates both the first belt 153 and the second belt 154. Each level of the central pulley 151 may include a groove to engage the respective belt 153, 154. The elbow pulleys 156a,b are shown as single-level pulleys to guide a respective belt 153, 154. As shown, the second belt 154 is positioned above the first belt 153. The first belt 153 is wrapped around the first level of the central pulley 151 and the first elbow pulley 156a while second belt 154 is wrapped around the second level of the central pulley 151 and the second elbow pulley 156b.

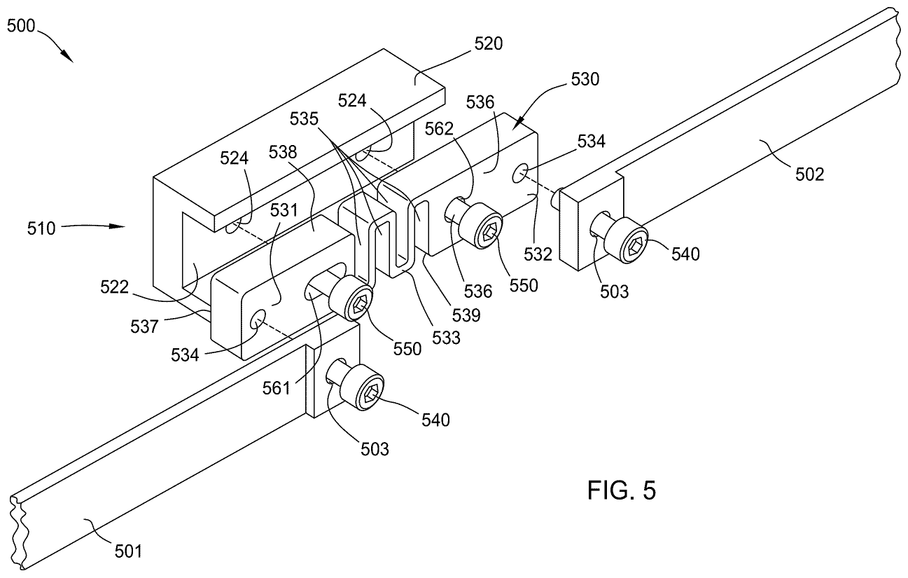

In some embodiments, and as shown in FIGS. 1B and 1C, the first belt 153 and second belt 154 may each be at a desired tension during operation of the swapper 130 to facilitate the movement of the arms 141, 142. In some embodiments, the first belt 153 and second belt 154 each have an in-line tensioner 155 to maintain the tension of the belt. The in-line tensioner 155 is fixed to both ends of the corresponding belt 153, 154. The in-line tensioner 155 may be adjusted to apply a desired tension the corresponding belt 153, 154. In some embodiments, the corresponding belt 153, 154 may be stretched to a desired tension and then each end of the corresponding belt 153, 154 is fastened to the tensioner to hold the belt in tension. In some embodiments, the in-line tensioner 155 described herein may be the in-line tensioner 510 shown in FIG. 5. In some embodiments, the first belt 153 and second belt 154 each have a width (extending in the direction of first height H1) that is about 8 mm to fit within the interior chamber 134. Additionally, the first and second belts 153, 154 may each also have a thickness of at least 0.08 mm to max stress applied to the belt, which includes the torque working load, pre-load of the tensioners 155, and the bending. In some embodiments, the belts 153, 154 have a thickness between 0.08 mm to 0.12 mm, such having a thickness of 0.08 mm, such having a thickness of 0.09 mm, such having a thickness of 0.1 mm, such having a thickness of 0.11 mm, such having a thickness of 0.12 mm.

Each arm 141, 142 has a shaft 157. The shaft 157 of the first arm 141 is attached to the first elbow pulley 156a and the shaft 157 of the second arm 142 is attached to the second elbow pulley 156b. For example, the shaft 157 of each arm may be attached to an outer race of the respective elbow pulley 156a,b. The first elbow pulley 156a, and thus the first arm 141, rotates about a first elbow axis 149a. The second elbow pulley 156b, and thus the second arm 142, rotates about a second elbow axis 149b.

Each of the elbow pulleys 156a,b may include bearing elements 158 to facilitate the rotation of the shaft 157, and thus the respective arm 141, 142, relative to the base 131. For example, an inner race of each elbow pulley 156a,b may be mounted on a mounting shaft 136 of the base 131. An outer race is engaged with the respective belt 153, 154. The bearing elements 158 allow an outer race of each pulley 156a,b to rotate relative to the inner race.

FIG. 1B shows the motor assembly 160 connected with one swapper 130, which is representative of the connection of the motor assembly 160 with the other swapper 130 shown in FIG. 1A. The motor assembly 160 extends through the lower wall of the housing 122. The motor assembly 160 includes a motor 161 that rotates first shaft 162. The motor assembly 160 may include seals between components to prevent in inflow of gases into the swapper chamber 123 through the motor assembly 160.

As the base 131 rotates, the elbow pulleys 156a,b rotate (e.g., orbit) around the central pulley 151 which does not rotate. The first belt 153 causes the first elbow pulley 156a to rotate as the base 131 rotates relative to the central pulley 151, thereby rotating the first arm 141 about the first elbow axis 149a. Similarly, the second belt 154 causes the second elbow pulley 156b to rotate about as the base 131 moves relative to the central pulley 151, thereby rotating the second arm 142 about the second elbow axis 149b.

The ratio of the central pulley 151 to each elbow pulley 156a,b is configured to achieve a desired shape and resolution of the path (e.g., linear movement) in which the substrate 105 is transferred between the load lock 170 and processing chamber 110. In some embodiments, the central pulley 151 has diameter twice the diameter of the elbow pulleys 146a,b (e.g., 2:1 ratio) to achieve the linear trajectory 146.

As shown in FIG. 1B, a distance D1 extends from the central axis 132 to each elbow axis 149a,b. In other words, each elbow pulley 146a,b is positioned on the base 131 at the same distance (shown as D1) from the central axis 132. The distance between the center point 147 and respective elbow axis 149a,b of the first and second arm 141, 142 is shown as D2. This distance D2 is the same as distance D1. In some embodiments, the distances D1 and D2 may be selected based on the desired reach (e.g., distance between the central axis 132 and the center point 147 when the arms 141, 142 are extended) of the swapper 130.

In some operations of the cluster tool 100, the substrate 105 may not be centered above the center point 147 of an arm 141, 142. In some embodiments, the distances D1 and D2 are selected to allow the swapper 130 to align the center of the substrate 105 within the processing chamber 110 and/or load lock 170.

Referring back to FIG. 1A, the swapper 130 on the right-hand side of the cluster tool 100 is shown in the first extended position. As shown, the central axis 132 and the elbow axes 149a, 149b are not aligned when the swapper 130 is in the first extended position. The first extended position of the arms 141, 142 is the nominal reach of the swapper 130. In other words, the center point 147 of the first and second arms 141, 142 will either be aligned with the center of substrate support 112 or the center of the load lock 170 when in the first extended position. The nominal reach of the first arm 141 is shown as nominal reach R1, which is representative of the nominal reach of the second arm 142.

Referring to FIG. 1A, the swapper 130 on the left-hand side of the cluster tool 100 is shown in the second extended position. As shown, the central axis 132 and the elbow axes 149a, 149b are aligned in the second extended position. The second extended position of the arms 141, 142 is an overreach position that places the center point 147 of the respective arm 141, 142 past the center of either the substrate support 112 or the load lock 170. The distance D1 and distance D2 may be selected such that the arms 141, 142 have an overreach sufficient to align an offset substrate 105 with either the center of the substrate support 112 or center of the load lock 170. The overreach of the first arm 141 is shown as overreach R2, which is representative of the overreach of the second arm 142. As shown in FIG. 1A, there is a differential, shown as R3, between the nominal reach R1 and overreach R2.

The arms 141, 142 may be extended to one or more positions between the first extended position and second extended position, including the second position, to correct the offset of the substrate 105. For example, the center point 147 moves along the trajectory 146 as the first arm 141 moves to one or more positions between the first position and the second position. A location center finder sensor (“LCF sensor”) may determine an offset between the center of the substrate 105 and the center point 147 of an arm 141, 142. The controller 190 may use the offset of the substrate 105 to determine a position between the first extended position and the second extended position that will place the center of the substrate 105 in alignment with the center of the substrate support 112. Thus, selecting a distance D1 and D2 that allows the arms 141, 142 to overreach extends the trajectory 146 to allow the center of the substrate 105 to be aligned along the distance of differential reach R3.

In some embodiments, the pulley system 150 is configured to allow for the swappers 130 to make full 360 degree rotations about the central axis 132. In some embodiments, the pulley system 150 may have limited rotation. For example, the pulley system 150 shown in FIGS. 1B and 1C allows for the base 131 to be rotated plus or minus 90 degrees about the central axis 132 from the retracted position (e.g., folded arms 141, 142 shown in FIG. 1B) to the second extended position shown in FIG. 1A. The in-line tensioner 155 of the first belt 153 and second belt 154 is positioned to allow the 90 degrees of rotation to extend the arms 141, 142 to the overreach position. The in-line tensioners 155, however, limit the overall rotation of the swapper 130 about the central axis 132 to avoid engaging the tensioners 155 with either the central pulley 151 or the respective elbow pulley 156a,b.

The first belt 153 and second belt 154 may precess (e.g., creep) around the central pulley 151 and the respective elbow pulleys 156a,b after repeated cycles of operation of the swapper 130. This belt precession can result in the arms 141, 142 deviating from the desired motion, such as causing a deviation in the trajectory 146. This belt precession can therefore interfere with aligning the center of the substrate 105 above the center of the processing chamber 110 and the load lock 170. The LCF sensors may be used to monitor for a drift in the motion of the swapper 130 that indicates that the first belt 153 and second belt 154 have moved out of alignment with the central pulley 151 and the respective elbow pulley 156a,b. For example, the LCF sensor may detect that the center of the substrate 105 deviates from an expected position at one or more positons of the arms 141, 142, which indicates that the arms 141, 142 are deviating from the desired motion. The swapper 130 is then serviced to adjust the alignment of the belts 153, 154 to the desired alignment to correct the motion of the arms 141, 142.

In some embodiments, the cluster tool includes three or more pairs of load locks 170 and processing chambers 110, and one swapper assembly 120 with a swapper 130 located between each pair of load locks 170 and processing chambers 110. In some embodiments, the cluster tool can have one or more levels of the plan view shown in FIG. 1A stacked on top of one another.

The controller 190 can be in communication with each motor assembly 160 to control the position of the arms 141, 142 of the swappers 130. In some embodiments, both swappers 130 may be moved synchronously. The controller 190 may include a programmable central processing unit (CPU) which is operable with a memory (e.g., non-transitory computer readable medium and/or non-volatile memory) and support circuits. The support circuits are coupled to the CPU and includes cache, clock circuits, input/output subsystems, power supplies, and the like, and combinations thereof coupled to the various components of the cluster tool 100, to facilitate control of the cluster tool 100. For example, in one or more embodiments the CPU is one of any form of general purpose computer processor used in an industrial setting, such as a programmable logic controller (PLC), for controlling various polishing system components and sub-processors. The memory, coupled to the CPU, is non-transitory and is one or more of readily available memory such as random access memory (RAM), read only memory (ROM), floppy disk drive, hard disk, or any other form of digital storage, local or remote.

Herein, the memory is in the form of a computer-readable storage media containing instructions (e.g., non-volatile memory), that when executed by the CPU, facilitates the operation of the cluster tool 100. The instructions in the memory are in the form of a program product such as a program that implements the methods of the present disclosure (e.g., middleware application, equipment software application, etc.). The program code may conform to any one of a number of different programming languages. In one or more embodiments, the disclosure may be implemented as a program product stored on computer-readable storage media for use with a computer system. The program(s) of the program product define functions of the embodiments (including the methods and operations described herein).

Illustrative computer-readable storage media include, but are not limited to: (i) non-writable storage media (e.g., read-only memory devices within a computer such as CD-ROM disks readable by a CD-ROM drive, flash memory, ROM chips or any type of solid-state non-volatile semiconductor memory) on which information is permanently stored; and (ii) writable storage media (e.g., floppy disks within a diskette drive or hard-disk drive or any type of solid-state random-access semiconductor memory) on which alterable information is stored. Such computer-readable storage media, when carrying computer-readable instructions that direct the functions of the methods described herein, are embodiments of the present disclosure.

The various methods and operations disclosed herein may generally be implemented under the control of the CPU of the controller 190 by the CPU executing computer instruction code stored in the memory (or in memory of a particular processing chamber) as, e.g., a software routine. When the computer instruction code is executed by the CPU, the CPU controls the components of the cluster tool 100 to conduct operations in accordance with the various methods and operations described herein. In one or more embodiments, the memory (a non-transitory computer readable medium) includes instructions stored therein that, when executed, cause the methods and operations described herein to be conducted. The operations described herein can be stored in the memory in the form of computer readable logic.

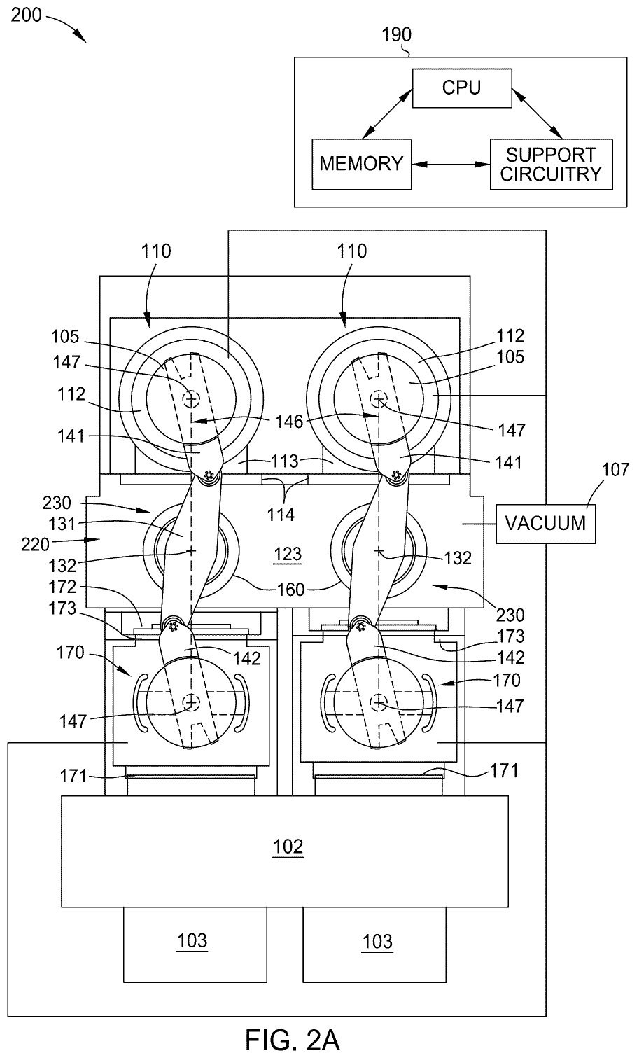

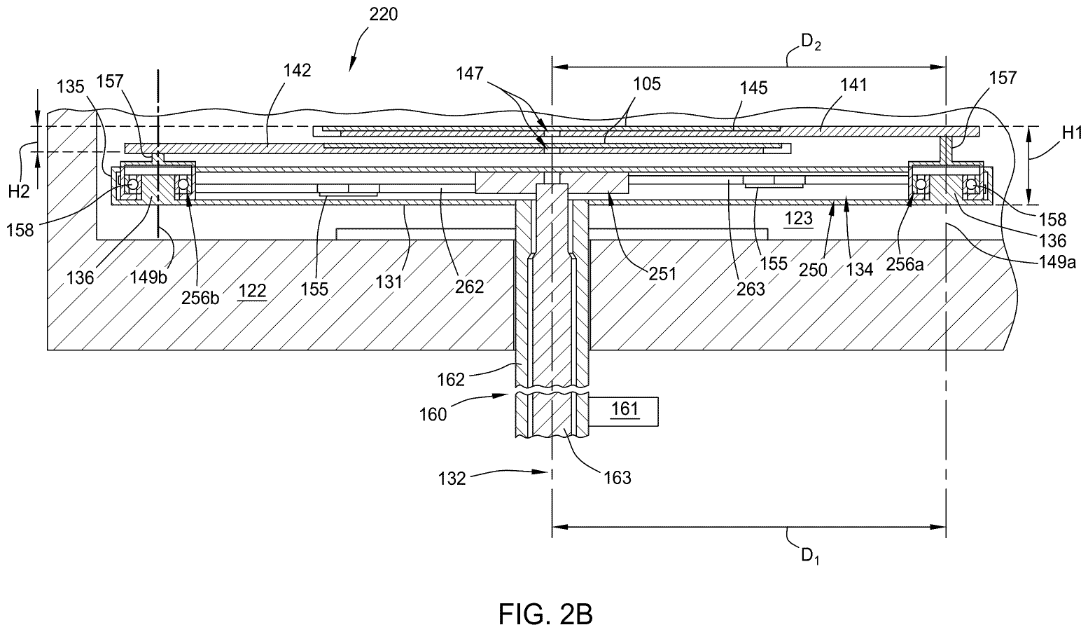

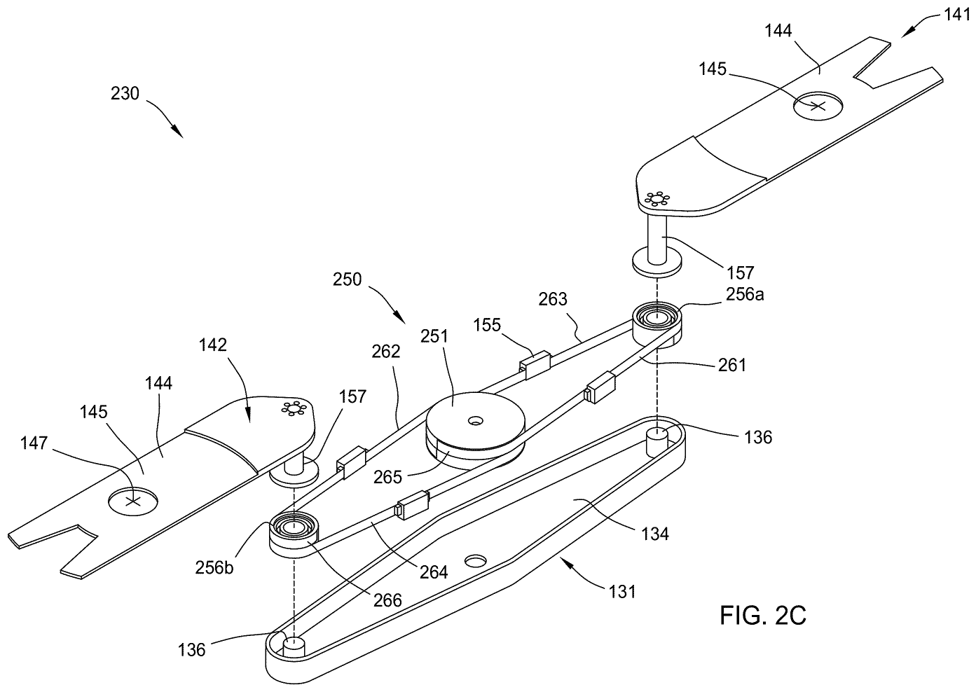

FIG. 2A illustrates a schematic plan view of a cluster tool 200. The cluster tool 200 has similar components of cluster tool 100 as indicated by the reference signs without reciting the description of these components for brevity. As shown, the cluster tool 200 has a swapper assembly 220 substituted for the swapper assembly 120. The swapper assembly 220 has similar components as the swapper assembly 120 as indicated by the reference signs without reciting the description of these components of the swapper assembly 120 for brevity. The swappers 230 of cluster tool 200 have a pulley system 250 (shown in FIGS. 2B, 2C) in place of pulley system 150.

FIG. 2B illustrates a schematic partial cross-sectional view of the swapper assembly 220 showing the arms 141, 142 in a retracted position. FIG. 2C illustrates a partial exploded view of the swapper 230 to show the interconnection of the pulley system 250 with other select components of the swapper 230.

As shown, the pulley system 250 of the swapper 230 includes a central pulley 251, a first elbow pulley 256a, a second elbow pulley 256b, a first band 261, a second band 262, a third band 263, and a fourth band 264. Each of the bands 261-264 may be tensioned at the desired tension to facilitate the operation of the swapper 230. In some embodiments, each band 261-264 may each have an in-line tensioner 155.

The central pulley 251 is mounted similarly to central pulley 151, in that the central pulley 251 is fixed (e.g., stationary) and the base 131 is rotated relative to the central pulley 251 by the motor assembly 160. The central pulley 251 is a multi-level pulley, in that a first end of the first band 261 and a first end of the second band 262 are anchored to a first level of the central pulley 251 and a first end of the third band 263 and a first end of the fourth band 264 are anchored to a second level of the central pulley 251. In some embodiments, the bands 261-264 may be anchored to the central pulley 251 by an adhesive or a fastener. In some embodiments, the portion of bands 261-264 anchored to the central pulley may be equivalent to about 5 degrees of the arc of the central pulley 251. FIG. 2C illustrates a portion 265 of the second band 262 anchored to first level. This portion 265 is representative of the portions of the first band 261, third band 263, and fourth band 264 anchored to the central pulley 251.

The first and second elbow pulleys 256a,b are each similarly attached to a shaft 157 of a respective arm 141, 142. For example, the shaft 157 may be rotatably coupled to the outer race of a respective elbow pulley 256a,b that rotates relative to an inner race. Thus, the rotation of the first elbow pulley 256a causes the rotation of the first arm 141 and the rotation of the second elbow pulley 256b causes the rotation of the second arm 142. The first and second elbow pulleys 256a,b are each a multi-level pulley. A second end of the first band 261 is anchored to a first level of the first elbow pulley 256a, a second end of the second band 262 is anchored to a first level of the second elbow pulley 256b, a second end of the third band 263 is anchored to a second level of the first elbow pulley 256a, and a second end of the fourth band 264 is anchored to a second level of the second elbow pulley 256b. FIG. 2C illustrates a portion 266 of the second end of the second band 262 anchored to first level of the second elbow pulley 256b. This portion 266 is representative of the portion of the fourth band 264 anchored to the second elbow pulley 256b and representative of the portion of the first band 261 and third band 263 anchored to the second elbow pulley 256a. In some embodiments, the portion of the second of the bands 261-264 anchored to an elbow pulley 256a,b may be equivalent to about 5 degrees of the arc of the elbow pulley 256a,b.

As shown in FIGS. 2B and 2C, the first band 261 and second band 262 are disposed above the third band 263 and fourth bands 264. In other words, the pulley system 250 has stacked bands.

As the base 131 rotates, the elbow pulleys 256a,b rotate (e.g., orbit) around the stationary central pulley 251. The first band 261 and third band 263 cause the first elbow pulley 256a to rotate as the base 131 rotates relative to the central pulley 251, thereby rotating the first arm 141 about the first elbow axis 149a. Similarly, the second band 262 and fourth band 264 cause the second elbow pulley 256b to rotate as the base 131 moves relative to the central pulley 251, thereby rotating the second arm 142 about the second elbow axis 149b.

The rotation of the swapper 230 about the central axis 132 is limited since a portion of each end of the bands 261-264 is anchored to the pulleys. For example, the base 131 may only be able to rotate about the central axis 132 from the retracted position shown in FIG. 2B (e.g., perpendicular to the trajectory 146) by a range, the range being less than 90 degrees of rotation. The base 131 may rotate over the range in either a clockwise or counter-clockwise direction. For example, the range of rotation of the base 131 may be between 0 degrees and 85 degrees, such as between 0 degrees and 82 degrees, such as 0 degrees and 77 degrees.

FIG. 2A shows the swappers 230 in an extended position. As shown, the base 131 of each swapper 230 is rotated counter clockwise from the retracted position shown in FIG. 2B. As shown, the central axis 132 and the elbow axes 149a, 149b are not aligned, such as what is shown in the second extended position of left-hand side swapper 130 of FIG. 1A, when the swapper 230 is in the extended position due to the limitations on rotation resulting from part of the bands 261-264 being wrapped around a pulley of the pulley system 250. The swappers 230, however, both are operable to move the substrate 105 along the substantially linear trajectory 146. The arms 141, 142 may be moved to an overreach position based on the remaining ability of the pulley system 250 to rotate the arms 141, 142.

As shown in FIG. 2A, the base 131 of the swapper 230 is partially disposed in the tunnel 113 and opening 173 when the swapper 230 is in the extended position. The swapper 230 is sized to fit within the tunnel 113 and opening 173 without contact. For example, and as shown in FIG. 2B, the swapper 230 similarly has a height H1 from the underside of the base 131 to the top of the first arm 141. This height H1 is less than the height of the opening of the tunnel 113 of the processing chamber 110 and the height of the opening of the opening 173 in the load lock 170. For example, the opening 173 and tunnel 113 may have a height that is at least 50 mm. The base 131 may have a height of about 20 mm. The distance from the upper surface of the base 131 to the upper surface of the second arm 142 may also be about 20 mm. Thus, the first height may be 40 mm, thereby allowing the swapper 230 to enter and exit the opening 173 and tunnel 113 with a clearance therebetween.

FIG. 2A shows a substrate 105 placed on the support 144 of each arm 141, 142. A portion of each arm 141, 142 is shown in dashed to illustrate that the substrate 105 is supported on the corresponding arm 141, 142. The center point 147 of each arm 141, 142 will follow the trajectory 146 as the motor assembly 160 operates the swapper 230 to move the arms 141, 142. As shown in FIG. 2A, the trajectory 146 (shown as a line) is a substantially linear path that extends from the center point of the substrate support 112, over the central axis 132 of the swapper 230, to a center point of the load lock 170. In other words, the center point 147 moves linearly as the first arm 141 and second arm 142 swap positions. The substrate 105 disposed on the support 144 of each arm 141, 142 similarly moves in a linear fashion. Thus, the swapper 130 is used to move the substrates in a linear trajectory between the load lock 170 and processing chamber 110, and vice versa. The arms 141, 142 move the substrate 105 disposed thereon along parallel linear trajectories that are separated by a distance since each arm 141, 142 is located at a different height. And, as shown in FIG. 2A, each pair of processing chambers 110 and load locks 170 are positioned opposing each other across the swapper assembly 120 such that the linear trajectory of the substrates 105 moved by one swapper 230 is parallel to the linear trajectory of the substrates 105 moved by the other swapper 230.

The ratio of the central pulley 251 to each elbow pulley 256a,b is configured to achieve a desired shape and resolution of the path (e.g., linear movement) in which the substrate 105 is transferred between the load lock 170 and processing chamber 110. In some embodiments, the central pulley 251 has a diameter that is twice the diameter of the elbow pulleys 256a,b (e.g., 2:1 ratio) to achieve the linear trajectory 146.

The base 131 of the swapper 230 similarly has a first distance D1 extending from the central axis 132 to each elbow axis 149a,b. Each arm 141, 142 similarly has a second distance D2 between the center point 147 and the respective elbow axis 149a,b. The first distance D1 and second distance D2 are the same distance. In some embodiments, the first distance D1 and second distance D2 of the swapper 230 exceed the distances D1, D2 of the swapper 130 shown in FIG. 1A. The housing 122 of the swapper assembly 220 may be wider, as compared to the swapper assembly 120, such that the swapper chamber 123 is large enough to accommodate the movement and placement of swappers 230 to prevent the two swappers 230 from contacting one another or from contacting the housing 122.

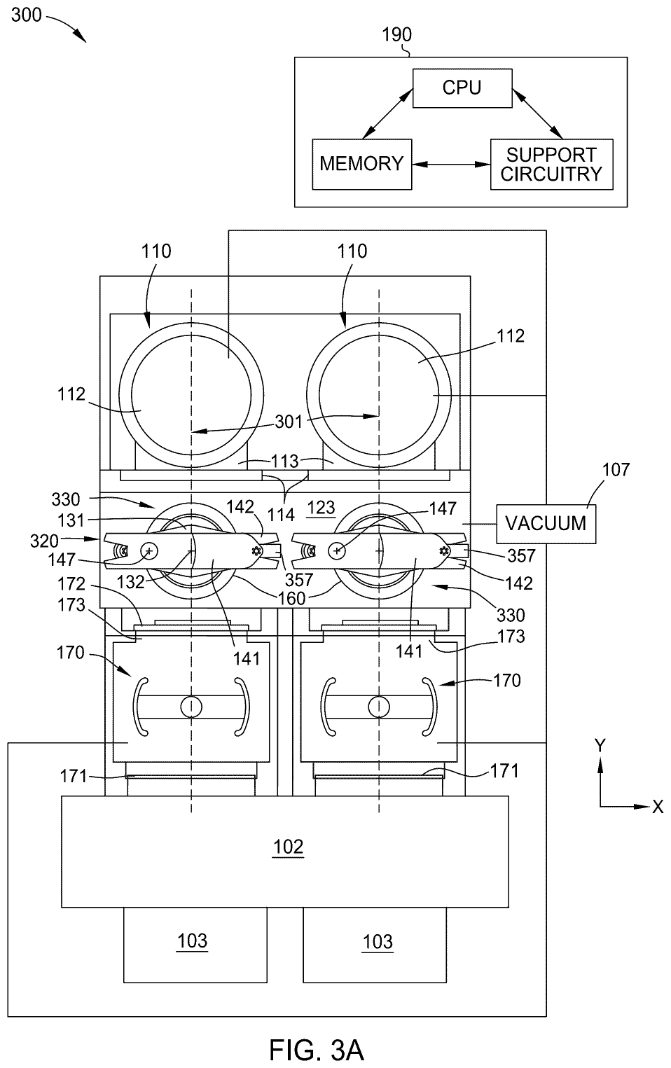

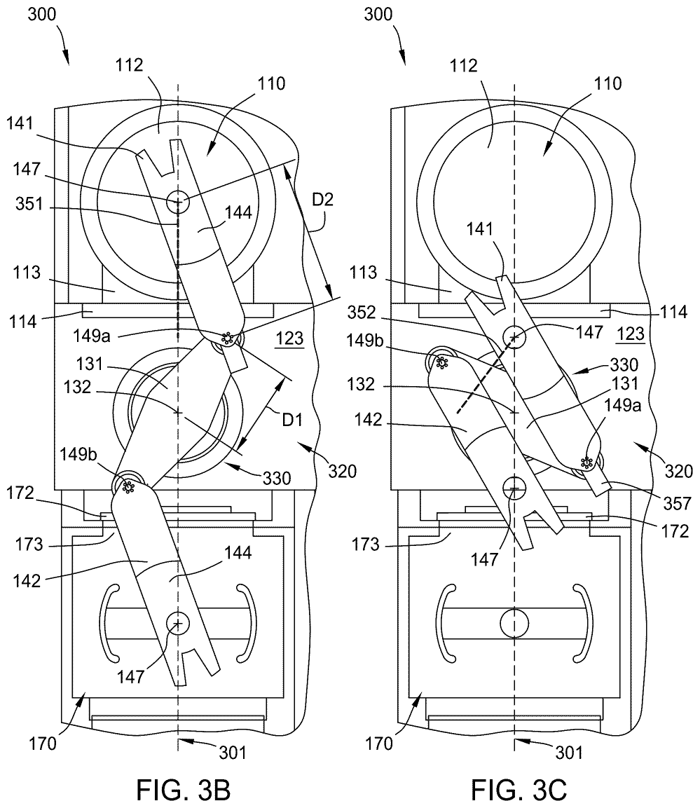

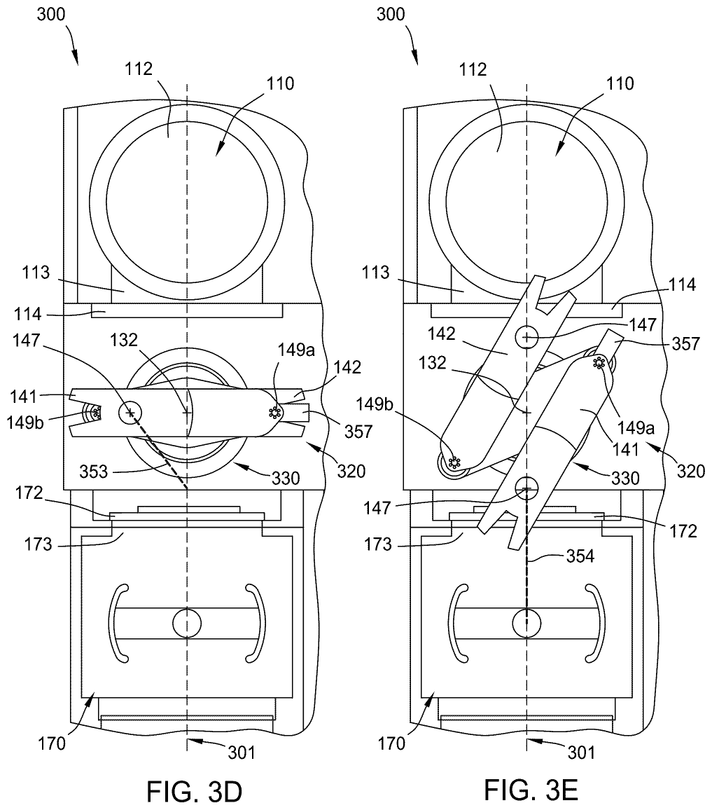

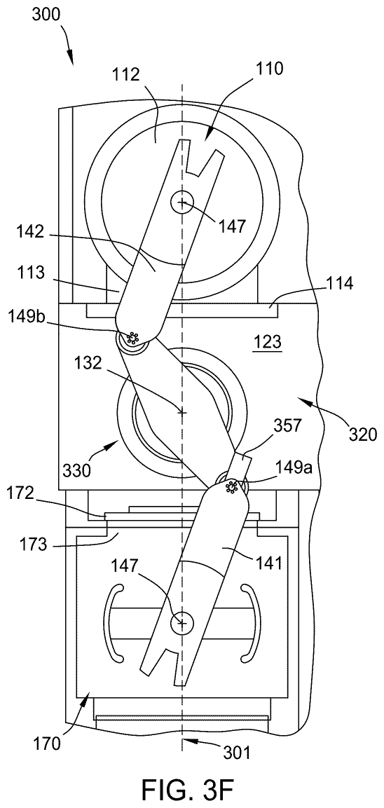

FIG. 3A illustrates a schematic plan view of a cluster tool 300. The cluster tool 300 has similar components of cluster tool 100 as indicated by the reference signs without reciting the description of these components for brevity. As shown, the cluster tool 300 has a swapper assembly 320 substituted for the swapper assembly 120. The swapper assembly 320 has similar components as the swapper assembly 120 as indicated by the reference signs without reciting the description of these components of the swapper assembly 120 for brevity.

As shown, two swappers 330 are shown disposed in the swapper chamber 123. The swappers 330 are similar to the swappers 130, 230 discussed above. Each swapper 330 is shown with the first arm 141 and second arm 142 a retracted (e.g., crossed) position. Each swapper 330 is configured to swap a substrate 105 disposed on an arm 141, 142 between a load lock 170 and a processing chamber 110. The substrates 105 are not shown on the arms 141, 142 for clarity.

The swapper 330 of cluster tool 300 similarly has a first distance D1 (shown in FIG. 3B) extending between the central axis 132 and the respective elbow axis 149a,b. The arms 141, 142 of swapper 330 similar have a second distance D2 (shown in FIG. 3B) extending between the center point 147 and the respective elbow axis 149a,b. The first distance D1 and second distance D2, however, are not equal. The first distance D1 is less than the second distance D1. In some embodiments, the second distance D2 may exceed the first distance D1 by more than 100 mm. The second distance D2 may be selected based on the depth of the process station 110 such that the arms 141, 142 can reach into the process station 110 to place the substrate 105 above the substrate support 112.

The first distance D1 is selected such that the ends of the base 131 are in the swapper chamber 123 but do not extend into either the opening 173 or tunnel 113 when the arms 141, 142 are in the extended position as shown in FIG. 3B. In other words, the ends of the elbow axes 149a,b are disposed in the swapper chamber 123 when the arms 141, 142 are in the extended positions. The first arm 141 is disposed above the second arm 142. The opening 173 and tunnel 113 of cluster tool 300 are sized to accommodate the height between the underside of the second arm 142 and the topside of the first arm 141 since the arms 141, 142 are positioned at different heights, which is analogous to the second height H2 shown in FIG. 1. Thus, the height dimension of the opening 173 and tunnel 113 of cluster tool 300 may be smaller than in both cluster tools 100 and 200 since the arms 141, 142 of the swapper 330, and not the base 131, extend into the opening 173 and tunnel 113. In some embodiments, the height dimension of the opening 173 and tunnel 113 may be at least 35 mm to accommodate the arms 141, 142 of the swapper 230.

The second slit valve 172 is sized to cover the opening 173 and the slit valve 114 is sized to cover the tunnel 113. A smaller dimension of the opening 173 and tunnel 113 may be covered with a smaller slit valve, and the slit valve may thus have a smaller actuator to move the slit valve between an open and closed position. Reducing and/or minimizing the height dimension of the opening 173 and tunnel 113 therefore reduce costs due to the reduction in size of the slit valve 114 and second slit valve 172. Additionally, decreasing the size of the slit valves reduces the amount of particles caused by opening and closing the valve. Additionally, reducing the height of the tunnel 113 reduces the overall volume of the tunnel 113, which reduces thermal non-uniformities within the processing chamber 110 while the substrate 105 is processed.

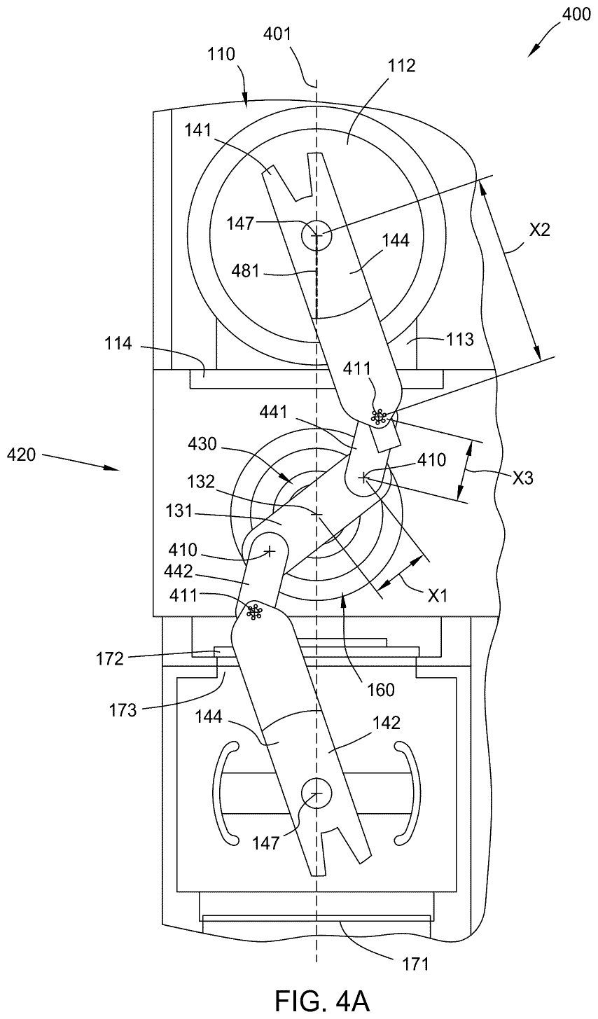

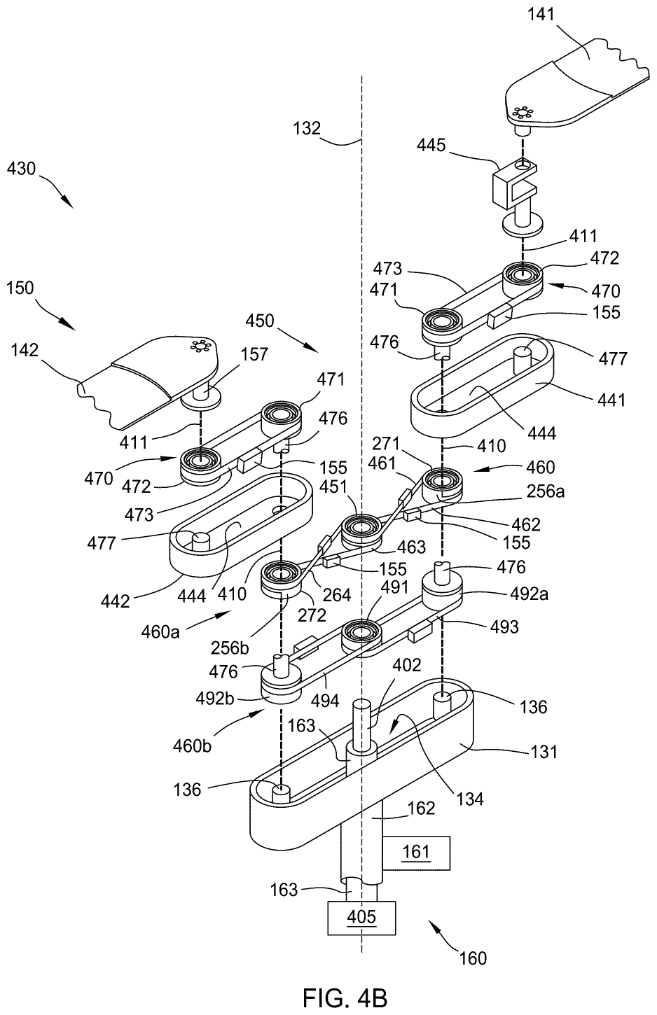

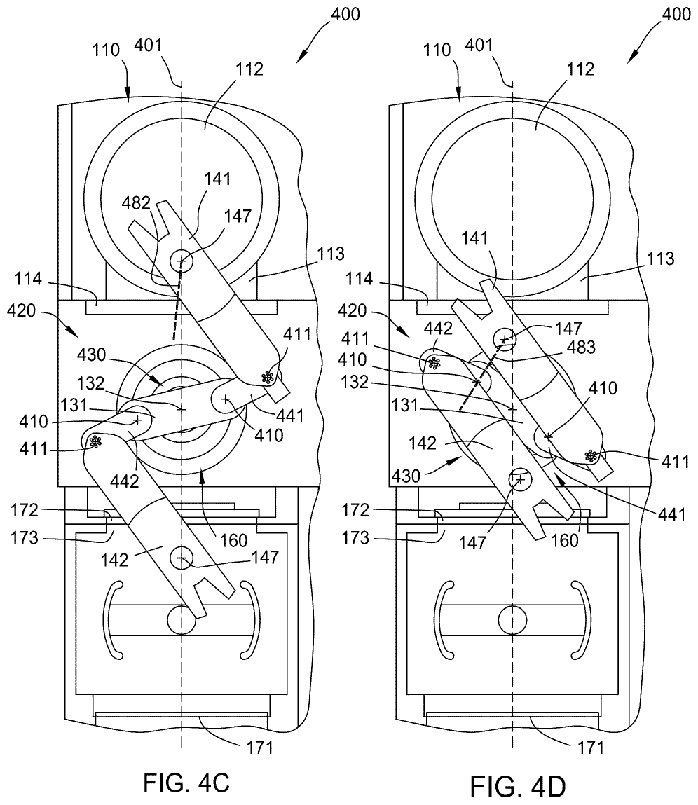

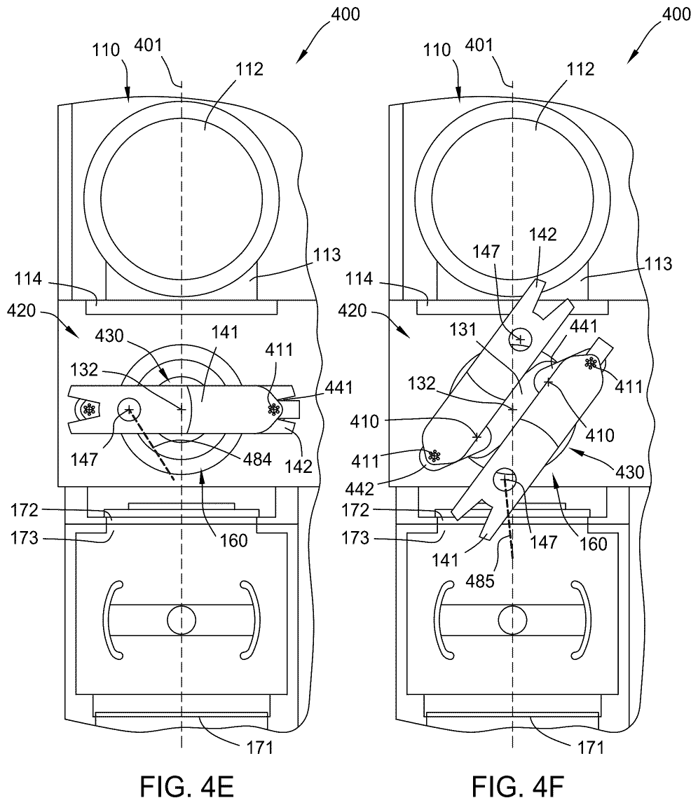

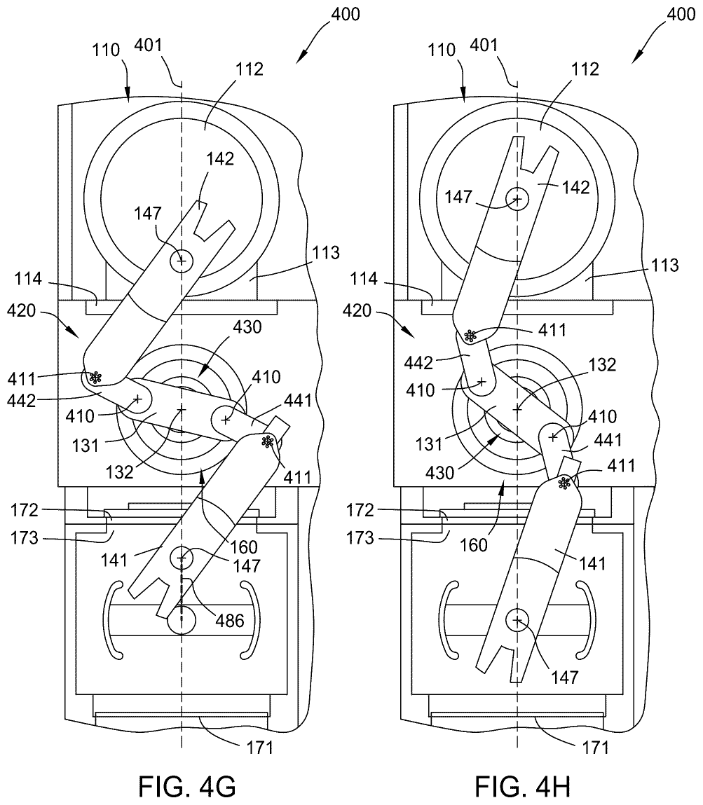

The shaft 357 of the first arm 141 of the swapper 330 is configured to allow the substrate 105 on to pass through the first elbow axis 149a. The shaft 357 of the first arm 141 may be a C-shaped member, such as shaft 457 in FIG. 4B, to allow the substrate 105 on the second arm 142 to pass underneath the first arm 141 and to pass through the first elbow axis 149a without contacting the first arm 141.

FIGS. 3B-3F illustrate a partial plan view of the cluster tool 300 to show a sequence of operating the swapper 330 to swap the arms 141, 142. FIGS. 3B-3D illustrate moving the first arm 141 and second arm 142 from an extended position to a retracted position. FIGS. 3E and 3F illustrate moving the first and second arm 142 from the retracted position to an extended position. Substrates 105, while substrates 105 not shown on the arms 141, 142 in FIGS. 3B-3F, may be disposed on the first and second arms 141, 142.

The swapper 330 makes a first coordinated movement and a second coordinated movement to retract the arms 141, 142. The swapper 330 similarly makes a first and second coordinated movement to extend the arms 141, 142. FIGS. 3B through 3F show a trajectory taken by the center point 147 of the first arm 141 as the first arm 141 is moved from the processing chamber 110 to the load lock 170. This trajectory is representative of the trajectory traveled by the second arm 142 while the first arm 141 is moved. As shown, the trajectory has a first trajectory segment 351 (FIG. 3B), a second trajectory segment 352 (FIG. 3C), a third trajectory segment 353 (FIG. 3D), and a fourth trajectory segment 354 (FIG. 3E).

The motor assembly 160 operates a first motor to rotate the first shaft 162 to rotate the base 131 about the central axis 132. The swapper 330 has a pulley system, such as pulley system 150 or pulley system 250, configured to move the arms 141, 142 along a trajectory to extend and retract the arms 141, 142. The central pulley, such as central pulley 151, 251, is not fixed on a stationary second shaft 163. Instead, the second shaft 163 is rotated by a second motor (see second motor 405 in FIG. 4B), allowing the central pulley to be rotated about the central axis 132. The second motor is selectively operated to rotate the central pulley to rotate the elbow pulley connected to each arm 141, 142, such as elbow pulleys 156a, 156b or elbow pulleys 256a, 256b, thereby rotating the arms 141, 142 relative to the base 131. The movement of the base 131 and arms 141, 142 are coordinated to move each arm 141, 142 along the trajectory. In some embodiments, the elbow pulleys of the swapper 330 may have a non-circular profile, such as a cam profile, unlike elbow pulleys 156a,b and elbow pulleys 256a,b, to move the arm 141, 142 along the desired trajectory due to the dimensions of first distance D1 and the second distance D2.

FIG. 3B illustrates the arms 141, 142 of the swapper 330 in an extended position. The first arm 141 is in the processing chamber 110 and the second arm 142 is in the load lock 170. The first trajectory segment 351 is shown as a dashed line. The first trajectory segment 351 shows the travel path of the center point 147 of the first arm 141 from the extended position shown in FIG. 3B to the partially retracted position shown in FIG. 3C. The swapper 330 makes a first coordinated retraction movement to move the first arm 141 from the extended position to the partially retracted position along the first trajectory segment 351. The first motor causes the base 131 to rotate about the central axis 132 in a clockwise direction. The second motor simultaneously actuates the pulley system to rotate the first arm 141 in a counter clockwise direction to move the center point 147 along the first trajectory segment 351. As shown in FIG. 3B, the first trajectory segment 351 is a substantial linear path that withdraws the center point 147 from the processing chamber 110 through the tunnel 113 and into the swapper chamber 123. The substantially linear path of the first trajectory segment 351 allows the substrate 105 to be moved with the first arm 141 without contacting an interior surface of the processing chamber 110. The first trajectory segment 351, as shown in FIG. 3B, extends along an axis 301 that extends through the centers of the processing chamber 110 and load lock 170 as well as through the central axis 132 of the swapper 330. The second arm 142 will make a similar movement as the first arm 141 to move from the extended position shown in FIG. 3B to the partially retracted position shown in FIG. 3C.

FIG. 3C shows the first arm 141 in the partially retracted position after following the first trajectory segment 351 from the extended position shown in FIG. 3B. The second arm 142 is similarly in the partially retracted position. The second trajectory segment 352 is shown as a dashed line. The second trajectory segment 352 shows the travel path of the center point 147 of the first arm 141 from the partially retracted position shown in FIG. 3C to the retracted position shown in FIG. 3D. As shown, the second trajectory segment 352 extends at an angle relative to the first trajectory segment 351 and is thus disposed at an angle relative to the axis 301. The swapper 330 makes a second coordinated retraction movement to move the first arm 141 from the partially retracted position shown in FIG. 3C to the retracted position shown in FIG. 3D. The first motor causes the base 131 to rotate about the central axis 132 in a counter clockwise direction from the position shown in FIG. 3C. The second motor simultaneously actuates the pulley system to rotate the first arm 141 in the counter clockwise direction to move the center point 147 along the second trajectory segment 352. The second trajectory segment 352 is shown as a being substantially linear. The non-circular profile of the elbow pulleys facilitates this substantially linear trajectory of the second trajectory segment 352. In some embodiments, the second trajectory segment 352 may not be substantially linear, but instead may be another non-linear trajectory, such as being an arcuate trajectory. For example, the second trajectory segment 352 may be an arcuate trajectory if the elbow pulleys have a non-circular profile. The second arm 142 will make a similar movement as the first arm 141 to move from the partially retracted position shown in FIG. 3C to the retracted position shown in FIG. 3D.

FIG. 3D shows the arms 141, 142 of the swapper 330 in the retracted position. The swapper 230 is further operated to move the first arm 141 into the load lock 170. The third trajectory segment 353 is shown as a dashed line. The third trajectory segment 353 shows the travel path of the center point 147 of the first arm 141 from the retracted position shown in FIG. 3D to a partially extended position shown in FIG. 3E. As shown, the third trajectory segment 353 extends at an angle relative to the second trajectory segment 352 and is thus disposed at an angle relative to the axis 301. The swapper 330 makes a first coordinated extension movement to move the first arm 141 from the retracted position shown in FIG. 3D to the partially extended position shown in FIG. 3E. The first motor causes the base 131 to rotate about the central axis 132 in a counter clockwise direction from the position shown in FIG. 3D. The second motor simultaneously actuates the pulley system to rotate the first arm 141 in the counter clockwise direction to move the center point 147 along the third trajectory segment 353. The third trajectory segment 353 is shown as a being substantially linear. In some embodiments, the second trajectory segment 352 may not be substantially linear, but instead may be another non-linear trajectory, such as being an arcuate trajectory. The second arm 142 will make a similar movement as the first arm 141 to move from the retracted position shown in FIG. 3D to the partially extended position shown in FIG. 3E.

FIG. 3E shows the arms 141, 142 of the swapper 330 in the partially extended position. The swapper 330 is further operated to move the first arm 141 into the load lock 170. The fourth trajectory segment 354 is shown as a dashed line. As shown, the fourth trajectory segment 354 is at an angle relative to the third trajectory segment 353, and the fourth trajectory segment 354 is collinear with the axis 301. The swapper 330 makes a second coordinated extension movement to move the first arm 141 from the partially extended position shown in FIG. 3E to the extended position shown in FIG. 3F. The first motor causes the base 131 to rotate about the central axis 132 in a clockwise direction from the position shown in FIG. 3E. The second motor simultaneously actuates the pulley system to rotate the first arm 141 in the counter clockwise direction to move the center point 147 along the fourth trajectory segment 354. The second arm 142 will make a similar movement as the first arm 141 to move from the partially extended position shown in FIG. 3E to the extended position shown in FIG. 3F.

FIG. 3F shows the swapper 330 in an extended position such that the first arm 141 is disposed within the load lock 170 and the second arm 142 is positioned within the processing chamber 110. In other words, the first arm 141 and second arm 142 has swapped positions with the placement shown in FIG. 3B. The first arm 141 and second arm 142 may be returned to the extended position shown in FIG. 3B by reversing the movements of the swapper 330. The swapper 330 can move as described to swap substrates 105 disposed on the arms 141, 142 between the processing chamber 110 and the load lock 170.

In some embodiments, the swapper 330 is extended to place a substrate 105 into the processing chamber 110. After the substrate 105 is transferred to the lift pins of the substrate support 112, the swapper 330 may be moved to the retracted position to allow the slit valve 114 to close during processing.

The swapper 330 allows for center correction of the substrate 105 in both the X and Y directions. FIG. 3A shows the X and Y directions, the X-direction extending in the same direction of the axis 301 and the Y-direction being perpendicular to the X-direction. For example, the first and second motor may coordinate the movement of the base 131 and arms 141, 142 to align the center of the substrate 105, which is offset from the center point 147 in both the X and Y directions, above the center point of the processing chamber 110 and load lock 170.

FIG. 4A illustrates a partial plan view of an exemplary cluster tool 400. The cluster tool 400 has similar components as the cluster tool 100 as indicated by the reference signs without reciting the description of these components for brevity. As shown, the cluster tool 400 has a swapper assembly 420 substituted for the swapper assembly 120. The swapper assembly 420 has similar components as the swapper assembly 120 as indicated by the reference signs without reciting the description of these components of the swapper assembly 120 for brevity. FIG. 4A illustrates one load lock 170 paired with a processing chamber 110 with a swapper 430 of the swapper assembly 420 shown in between. The cluster tool 400 may have multiple pairs of load locks 170 and processing chambers 110, each pair having a swapper 430 disposed between.

As shown, a swapper 430 is shown disposed in the swapper chamber 123 of the swapper assembly 420. The swapper 430 is similar to the swappers 130, 230 discussed above. The swapper 430 is shown in an extended position with the first arm 141 disposed in the processing chamber 110 and the second arm 142 disposed in the load lock 170. A substrate 105 is not shown on the arms 141, 142. Each swapper 430 is configured to swap a substrate 105 disposed on an arm 141, 142 between a load lock 170 and a processing chamber 110.

The swapper 430 includes a base 131, a first arm 141, a second arm 142, a first link 441, a second link 442, and a pulley system 450 (shown in FIG. 4B). The first arm 141 is pivotally connected to the first link 441. The second arm 142 is pivotally connected to the second link 442. The first and second links 441, 442 are each pivotally connected to the base 131. The pulley system 450 is configured to move the first link 441, second link 442, first arm 141, and second arm 142.

As shown in FIG. 4B, the pulley system 450 includes a base pulley assembly 460 disposed in the base 131 and a link pulley system 470 disposed in each of the first link 441 and the second link 442. The base pulley assembly 460 includes a first base pulley system 460a and a second base pulley system 460b.

The first base pulley system 460a is similar to the pulley system 250 shown in FIG. 2B, in that the first base pulley system 460a includes multi-leveled pulleys with band segments extending between the pulleys. As shown, the first base pulley system 460a includes a first central pulley 451, a first elbow pulley 256a, and a second elbow pulley 256b. The first base pulley system 460a further includes a first band 461, a second band 462, a third band 463, and a fourth band 464. In some embodiments, each of the bands 461-464 may include an inline tensioner 155.

The first central pulley 451 is coupled to a third shaft 402 extending through the first shaft 162 and the second shaft 163. The first shaft 162 and second shaft 163 are independently rotatable relative to the third shaft 402. In some embodiments, the first central pulley 451 is a fixed (e.g., stationary) pulley mounted on a fixed (e.g., stationary) shaft 402 similar to central pulley 151. The base 131 is rotatable about the central axis 132, and thus rotatable relative to the first central pulley 451, by the first motor 161 (FIGS. 1B, 2B) of the motor assembly 160 that rotates the first shaft 162 to rotate the base 131. The first central pulley 451 has two levels to accommodate the bands 461-464 similar to central pulley 251 shown in FIG. 2C.

As explained above, the elbow pulleys 256a,b are two leveled pulleys. In some embodiments, the inner race of the first elbow pulleys 256a may be mounted to a link shaft 476 of the first link 441. The outer race of the first elbow pulley 256a may thus rotate about the link shaft 476 of the first link 441. The outer race of the first elbow pulley 256a is rotatably coupled to the first link 441 and coupled to the first band 461 and second band 462. The rotation of the first elbow pulley 256a caused by the first band 461 and second band 462 also causes the first link 441 to rotate relative to the base 131. The inner race of the second elbow pulley 256b may be mounted to a link shaft 476 of the second link 442. The outer race of the second elbow pulley 256b may thus rotate about the link shaft 476 of the second link 442. The outer race of the second elbow pulley 256b is rotatably coupled to the second link 442 and coupled to the third band 463 and fourth band 464. The rotation of the second elbow pulley 256b caused by the third and fourth bands 463, 464 also causes the second link 442 to rotate relative to the base 131.

The first band 461 and the second band 462 extend between the first central pulley 451 and the first elbow pulley 256a. A first end of the first band 461 is anchored to a first level of the first central pulley 451 and the second end of the first band 461 is anchored to a first level of the first elbow pulley 256a. A first end of the second band 462 is anchored to a second level of the first central pulley 451 and the second end of the second band 462 is anchored to a second level of the first elbow pulley 256a. However, the first and second bands 461, 462 do not extend parallel to one another between the pulleys similar to what is shown in in FIG. 2C. Instead, the first and second bands 461, 462 pass over (e.g., cross over) one another and are arranged in a “FIG. 8” configuration. As shown, the first end of the first band 461 extends from a first side of the first central pulley 451 while the second end of first band 461 extends to a second side of the first elbow pulley 256a. Similarly, the first end of the second band 462 extends from a second side of the first central pulley 451 while the second end of second band 462 extends to a first side of the first elbow pulley 256a. This configuration of the first band 461 and the second band 462 causes the first link 441 to rotate in the same rotational direction as the base 131, as the base 131 is rotated relative to the first central pulley 451.

The third band 463 and the fourth band 464 extend between the first central pulley 451 and the second elbow pulley 256b. A first end of the third band 463 is anchored to the first level of the first central pulley 451 and the second end of the third band 463 is anchored to a first level of the second elbow pulley 256b. A first end of the fourth band 463 is anchored to the second level of the first central pulley 451 and the second end of the fourth band 464 is anchored to a second level of the second elbow pulley 256b. The third and fourth bands 463, 464 similarly pass over one another and are arranged in a “FIG. 8” configuration. As shown, the first end of the third band 463 extends from the second side of the first central pulley 451 while the second end of the third band 463 extends to a first side of the second elbow pulley 256b. Similarly, the first end of the fourth band 464 extends from the first side of the first central pulley 451 while the second end of the fourth band 464 extends to a first side of the second elbow pulley 256b. This configuration of the third band 463 and the fourth band 464 causes the second link 442 to rotate in the same rotational direction as the base 131 as the base 131 is rotated relative to the first central pulley 451.

In some embodiments, the first central pulley 451 and elbow pulleys 256a,b have a 1:1 ratio to facilitate moving the center point 147 of each arm 141, 142 along a trajectory. In other words, every unit of rotation of the base in a rotational direction similarly causes the same unit of rotation of first link 441 and the second link 442.

The second base pulley system 460b includes a second central pulley 491, a first pulley 492a, and a second pulley 492b. The second central pulley 491 is fixed to the second shaft 163 extending through the first shaft 162. The second shaft 163 is rotatable by a second motor 405 of the motor assembly 160 to rotate the second central pulley 491 about the central axis 132. The second central pulley 491 is a multi-level pulley. In some embodiments, a first belt 493 may be engaged with a first level of the second central pulley 491 and a second belt 494 may be engaged with a second level of the second central pulley 491. The first belt 493 is looped around the first pulley 492a and the second central pulley 491. The second belt 494 is looped around the second pulley 492b and the second central pulley 491. Thus, the rotation of the second central pulley 491 causes the first and second pulleys 492a,b to rotate. In some embodiments, two band segments may extend between the second central pulley 491 and each pulley 492a,b in a similar manner as pulley system 250. In some embodiments, the second central pulley 491 and the pulleys 492a,b have a 1:1 ratio to facilitate moving the center point 147 of each arm 141, 142 along the trajectory. An inner race of the pulleys 492a,b may be mounted on a mounting shaft 136 of the base 131.

Each link 441, 442 has a link pulley system 470 disposed in a link chamber 444 formed within the respective link 441, 442. Each link pulley system 470 includes a first link pulley 471 and a second link pulley 472. A belt 473 is looped around the first link pulley 471 and second link pulley 472. The belt 473 causes the second link pulley 472 to rotate in response to the rotation of the first link pulley 471. In some embodiments, the belt 473 may instead be two segments extending between the first link pulley 471 and the second link pulley 472. The first link pulley 471 is rotatably coupled to one of the pulleys 492a,b of the second base pulley system 460b. In other words, the rotation of the pulleys 492a,b causes the first link pulley 471 connected thereto to rotate. The first link pulley 471 may be coupled to the link shaft 476 that extends through an opening in the bottom of the respective link 441, 442. Thus, one end of the link shaft 446 is rotatably connected to the one of the pulleys 492a,b while the other end is rotatably connected to one of the first link pulleys 471. In some embodiments, the link shaft 476 is rotatably connected with an outer race of the respective pulleys 492a,b. The rotation of the outer race of the first pulley 492a causes the first link pulley 471 in the first link 441 to rotate. The rotation of the outer race of the second pulley 492b causes the first link pulley 471 in the second link 442 to rotate.

The second link pulley 472 may be mounted on and rotate about a mounting shaft 477 fixed to a wall of the respective link 441, 442. The second link pulley 472 may have an inner race mounted to the shaft 477 and an outer race rotatable about the inner race that is engaged with and rotated by the belt 473. The second link pulley 472 of the first link 441 is rotatably coupled to the c-shaped shaft 445 of the first arm 141, such rotation of the second link pulley 472 by the belt 473 causes the first arm 141 to rotate. The second link pulley 472 of the second link 442 is rotatably coupled to the shaft 157 of the second arm 142, such that rotation of the second link pulley 472 by the belt 473 causes the second arm 142 to rotate.

The second motor 405 is used to actuate the second base belt assembly 460a and the two link pulley systems 470 to rotate the first arm 141 and the second arm 142 relative to the base 131 and relative to the respective link 441, 442. The first motor 161 is used to rotate the base 131 which causes the links 441, 442 to rotate in the same direction as the base 131 due to the first base pulley system 460a. The first motor 161 and the second motor 405 of the motor assembly 160 are coordinated to move the center point 147 of each of the arms 141, 142 along a desired trajectory. In some embodiments, the first link pulley 471 and the second link pulley 472 have a 1:1 ratio to facilitate moving the center point 147 of each arm 141, 142 along a trajectory.

The central axis 132 of the swapper 430 extends thorough the first central pulley 451 fixed on the third shaft 402. The first elbow pulley 256a, the first pulley 492a, and the first link pulley 471 disposed in the first link 441 rotate about an elbow axis 410. The second elbow pulley 256b, the second pulley 492b, and the first link pulley 471 disposed in the second link 442 similarly rotate about an elbow axis 410. Each second link pulley 472, and the respective arm 141, 142 attached thereto, rotates about an arm axis 411. In other words, each link 441, 442 rotates relative to the base 131 about an elbow axis 410, the first arm 141 rotates relative to the first link 441 about an arm axis 411, and the second arm 142 rotates relative to the second link 442 about an arm axis 411.

The swapper 430 of cluster tool 400 similarly has a first distance X1 (shown in FIG. 4A) extending between the central axis 132 and the respective elbow axis 410. The arms 141, 142 of swapper 430 have a second distance X2 (shown in FIG. 4A) extending between the center point 147 and the respective arm axis 411. The links 441, 442 each have a third distance X3 (shown in FIG. 4A) extending from the respective elbow axis 410 to the respective arm axis 411. The first distance X1 and second distance X2 are not equal distances. The first distance X1 is less than the second distance X2. In some embodiments, the second distance X2 may exceed the first distance X1 by more than 200 mm. In some embodiments, and as shown in FIG. 4A, the first distance X1 and third distance X3 are equivalent distances. The first distance X1, second distance X2, and third distance X3 may be selected based on the depth of the process chamber 110 such that the arms 141, 142 can reach into the process chamber 110 to place the substrate 105 above the substrate support 112.

The first distance X1 and third distance X3 are selected such that the ends of the base 131 and the ends of the links 441, 442 are in the swapper chamber 123 but do not extend into either the opening 173 or tunnel 113 when the arms 141, 142 are in the extended position as shown in FIG. 4A. In other words, the arm axes 411 are disposed in the swapper chamber 123 when the arms 141, 142 are in the extended positions. The first arm 141 is disposed above the second arm 142. The opening 173 and tunnel 113 of cluster tool 400 are sized to accommodate the height between the underside of the second arm 142 and the topside of the first arm 141 since the arms 141, 142 are positioned at different heights (similar to the height H2 shown in FIG. 1B). Thus, the height dimension of the opening 173 and tunnel 113 of cluster tool 400 may be smaller than in cluster tools 100 and 200 since the arms 141, 142 of the swapper 430, and not the base 131 or links 441, 442, extend into the opening 173 and tunnel 113. In some embodiments, the height dimension of the opening 173 and tunnel 113 may be between 30 mm to 50 mm, such as 35 mm, such as 40 mm, such as 45 mm, to accommodate the arms 141, 142 of the swapper 430. Reducing and/or minimizing the size of the opening 173 and tunnel 113 provides similar benefits as described above with respect to cluster tool 300.

The swapper 430 has a reduced overall length (from end to end) when in the retracted position (e.g., FIG. 4E) as compared to the swapper 330. In other words, the swappers 430 are more compact when in the retracted position than the swappers 330. Therefore, two swappers 430 may be housed in a smaller swapper chamber 123 as compared to two swappers 330.

The shaft 445 of the first arm 141 of the swapper 430 is configured to allow the substrate 105 on the second arm 142 to pass through the arm axis 411. The shaft 445 of the first arm 141 may be a C-shaped member, such as to allow the substrate 105 on the second arm 142 to pass underneath the first arm 141 without contacting the first arm 141.

The swapper 430 makes a first coordinated retraction movement, a second coordinated retraction movement, and a third coordinated retraction movement to retract the arms 141, 142 from an extended position. The swapper 430 similarly makes a first coordinated extension movement, a second coordinated extension movement, and a third coordinated extension movement to extend the arms 141, 142 from the retracted position. FIGS. 4A and 4C-4H show a trajectory taken by the first arm 141 as the first arm 141 is moved from the processing chamber 110 to the load lock 170. This trajectory is representative of the trajectory traveled by the second arm 142 while the first arm 141 is moved. As shown, the trajectory has a first trajectory segment 481 (FIG. 4A), a second trajectory segment 482 (FIG. 4C), a third trajectory segment 483 (FIG. 4D), a fourth trajectory segment 484 (FIG. 4E), a fifth trajectory segment 485 (FIG. 4F) and a sixth trajectory segment 486 (FIG. 4G). FIG. 4A shows the arms 141, 142 in the extended position, with the first arm 141 disposed in the processing chamber 110 and the second arm 142 disposed in the load lock 170. FIG. 4H shows the arms 141, 142 in the extended position after moving along the trajectory, in that the first arm 141 is now in the load lock 170 and the second arm 142 is now in the processing chamber 110.

The pulley system 450 is configured to move the arms 141, 142 along a trajectory to extend and retract the arms 141, 142. The motor assembly 160 operates a first motor 161 to rotate the first shaft 162 to rotate the base 131 about the central axis 132 and to rotate the base 131 relative to the first central pulley 451. The bands 461-464 cause the elbow pulleys 256a,b to rotate as the base 131 rotates relative to the first central pulley 451, thereby causing the links 441, 442 to rotate about the elbow axis 410. The second central pulley 491 is rotated about the central axis 132 by the second motor 405 of the motor assembly 160. The first motor 161 and the second motor 405 are coordinated to move the first link 441, second link 442, first arm 141, and second arm 142 such that the center point 147 of each arm 141, 142 follows along a desired trajectory.

FIG. 4A illustrates the arms 141, 142 of the swapper 430 in an extended position. The first arm 141 is in the processing chamber 110 and the second arm 142 is in the load lock 170. The first trajectory segment 481 is shown as a dashed line. The first trajectory segment 481 shows the travel path of the center point 147 of the first arm 141 from the extended position shown in FIG. 4A to a first partially retracted position shown in FIG. 4C. The swapper 430 makes a first coordinated retraction movement to move the first arm 141 from the extended position to the first partially retracted position along the first trajectory segment 481. The first motor 161 causes the base 131 to rotate about the central axis 132 in a clockwise direction, causing the first link 441 and the second link 442 to rotate relative to the base 131 in the clockwise direction. The second motor 405 simultaneously actuates the second pulley system 460b and link pulley system 470 in the first link 441 to rotate the first arm 141 in a counter clockwise direction to move the center point 147 along the first trajectory segment 481. As shown in FIG. 4A, the first trajectory segment 481 is a substantial linear path that moves center point 147 toward the tunnel 113. The substantially linear path of the first trajectory segment 481 allows the substrate 105 to be moved with the first arm 141 without contacting an interior surface of the processing chamber 110. The first trajectory segment 481, as shown in FIG. 4A, extends along an axis 401 that extends through the centers of the processing chamber 110 and load lock 170 as well as through the central axis 132 of the swapper 430. The second arm 142 will make a similar movement as the first arm 141 to move from the extended position shown in FIG. 4A to the first partially retracted position shown in FIG. 4C.

FIG. 4C shows the first arm 141 in the first partially retracted position after following the first trajectory segment 481 from the extended position shown in FIG. 4A. The second arm 142 is similarly in the first partially retracted position. The second trajectory segment 482 is shown as a dashed line. The second trajectory segment 482 shows the travel path of the center point 147 of the first arm 141 from the first partially retracted position shown in FIG. 4C to the second partially retracted position shown in FIG. 4D. As shown, the second trajectory segment 482 extends at an angle relative to the first trajectory segment 481 and is thus disposed at an angle relative to the axis 401. In some embodiments, the first trajectory segment 482 may be collinear with the first trajectory segment 481. The swapper 430 makes a second coordinated retraction movement to move the first arm 141 from the first partially retracted position shown in FIG. 4C to the second partially retracted position shown in FIG. 4D. The first motor 161 causes the base 131 to rotate clockwise about the central axis 132 from the position shown in FIG. 4C. The rotation of the base 131 relative to the first central pulley 451 causes the first base pulley system 460a to rotate first link 441 and the second link 442 in a clockwise direction relative to the base 131. The second motor 405 simultaneously actuates the second base pulley system 460b and the link pulley system 470 of the first link 441 to rotate the first arm 141 in a counter-clockwise direction to move the center point 147 along the second trajectory segment 482. The second trajectory segment 482 is shown as a being substantially linear. In some embodiments, the elbow pulleys 256a,b have a non-circular profile to facilitate this substantially linear trajectory of the second trajectory segment 482. In some embodiments, the second trajectory segment 482 may not be substantially linear, but instead may be another non-linear trajectory, such as being an arcuate trajectory. The second arm 142 will make a similar movement as the first arm 141 to move from the first partially retracted position shown in FIG. 4C to the second partially retracted position shown in FIG. 4D.

FIG. 4D shows the first arm 141 in the second partially retracted position after following the second trajectory segment 482 from the first partially retracted position shown in FIG. 4C. The center point 147 of the first arm 141 is shown as withdrawn from the tunnel 113 and is now located within the swapper assembly 420. The second arm 142 is similarly in the second partially retracted position. The third trajectory segment 483 is shown as a dashed line. The third trajectory segment 483 shows the travel path of the center point 147 of the first arm 141 from the second partially retracted position shown in FIG. 4D to the retracted position shown in FIG. 4E. As shown, the third trajectory segment 483 extends at an angle relative to the second trajectory segment 482 and is thus disposed at an angle relative to the axis 401. The swapper 430 makes a third coordinated retraction movement to move the first arm 141 from the second partially retracted position shown in FIG. 4D to the retracted position shown in FIG. 4E. The first motor 161 causes the base 131 to rotate about the central axis 132 in the counter clockwise direction from the position shown in FIG. 4D. The rotation of the base 131 relative to the first central pulley 451 causes the first base pulley system 460a to rotate first link 441 and the second link 442 in the counter-clockwise direction relative to the base 131. The second motor 405 simultaneously actuates the second base pulley system 460b and the link pulley system 470 of the first link 441 to rotate the first arm 141 in a counter-clockwise direction to move the center point 147 along the third trajectory segment 483. The third trajectory segment 483 is shown as a being substantially linear. In some embodiments, the non-circular profile of the elbow pulleys 256a,b facilitates this substantially linear trajectory of the third trajectory segment 483. In some embodiments, the third trajectory segment 483 may not be substantially linear, but instead may be another non-linear trajectory, such as being an arcuate trajectory. The second arm 142 will make a similar movement as the first arm 141 to move from the second partially retracted position shown in FIG. 4D to the retracted position shown in FIG. 4E.

FIG. 4E shows the arms 141, 142 of the swapper 430 in the retracted position. The first arm 141 is positioned over the second arm 142. The first arm 141 is also partially disposed over the second link 442 and the second arm 142 is partially disposed over the first link 441. The first and second links 441, 442 and the first and second arms 141, 142 are positioned such that the elbow axis 410 and the arm axis 411 are positioned perpendicular to the axis 401.

The swapper 430 is further operated from the retracted position to move the first arm 141 into the load lock 170. The fourth trajectory segment 484 is shown as a dashed line in FIG. 4E. The fourth trajectory segment 484 shows the travel path of the center point 147 of the first arm 141 from the retracted position shown in FIG. 4E to a first partially extended position shown in FIG. 4F. As shown, the fourth trajectory segment 484 extends at an angle relative to the third trajectory segment 483 and is thus disposed at an angle relative to the axis 401. The swapper 430 makes a first coordinated extension movement to move the first arm 141 from the retracted position shown in FIG. 4E to the first partially extended position shown in FIG. 4F along the fourth trajectory segment 484. The first motor 161 causes the base 131 to rotate about the central axis 132 in the counter-clockwise direction from the position shown in FIG. 4E. The rotation of the base 131 relative to the first central pulley 451 causes the first base pulley system 460a to rotate first link 441 and the second link 442 in the counter-clockwise direction relative to the base 131. The second motor 405 simultaneously actuates the second base pulley system 460b and the link pulley system 470 of the first link 441 to rotate the first arm 141 in the counter clockwise direction to move the center point 147 along the fourth trajectory segment 484. The fourth trajectory segment 484 is shown as a being substantially linear. In some embodiments, the fourth trajectory segment 484 may not be substantially linear, but instead may be another non-linear trajectory, such as being an arcuate trajectory. The second arm 142 will make a similar movement as the first arm 141 to move from the retracted position shown in FIG. 4E to the first partially extended position shown in FIG. 4F.

FIG. 4F shows the arms 141, 142 of the swapper 430 in the first partially extended position. The swapper 430 is further operated to move the first arm 141 into the load lock 170. The fifth trajectory segment 485 is shown as a dashed line. As shown, the fifth trajectory 485 is at an angle relative to the fourth trajectory segment 484, and the fifth trajectory segment 485 is angled with respect to the axis 401. The swapper 430 makes a second coordinated extension movement to move the first arm 141 from the first partially extended position shown in FIG. 4F to a second partially extended position shown in FIG. 4G. The first motor 161 causes the base 131 to rotate about the central axis 132 in the clockwise direction from the position shown in FIG. 4F. The rotation of the base 131 relative to the first central pulley 451 causes the first base pulley system 460a to rotate first link 441 and the second link 442 in the clockwise direction relative to the base 131. The second motor 405 simultaneously actuates the second base pulley system 460b and the link pulley system 470 of the first link 441 to rotate the first arm 141 in the counter-clockwise direction to move the center point 147 along the fifth trajectory segment 485. FIG. 4F shows the fifth trajectory segment 485 as being substantially linear. In some embodiments, the fifth trajectory segment 485 may be collinear with the sixth trajectory segment 486. In some embodiments, the fifth trajectory segment 485 may not be substantially linear, but instead may be another non-linear trajectory, such as being an arcuate trajectory. The second arm 142 will make a similar movement as the first arm 141 to move from the first partially extended position shown in FIG. 4F to the second partially extended position shown in FIG. 4G.

FIG. 4G shows the arms 141, 142 of the swapper 430 in the second partially extended position. The swapper 430 is further operated to move the first arm 141 into the load lock 170. The sixth trajectory segment 486 is shown as a dashed line. As shown, the sixth trajectory segment 486 is at an angle relative to the fifth trajectory segment 485, and the sixth trajectory segment 486 is collinear with the axis 401. The swapper 430 makes a third coordinated extension movement to move the first arm 141 from the second partially extended position shown in FIG. 4G to the extended position shown in FIG. 4H. The first motor 161 causes the base 131 to rotate about the central axis 132 in the clockwise direction from the position shown in FIG. 4F. The rotation of the base 131 relative to the first central pulley 451 causes the first base pulley system 460a to rotate first link 441 and the second link 442 in a clockwise direction relative to the base 131. The second motor 405 simultaneously actuates the second base pulley system 460b and the link pulley system 470 of the first link 441 to rotate the first arm 141 in the counter-clockwise direction to move the center point 147 along the sixth trajectory segment 486. The second arm 142 will make a similar movement as the first arm 141 to move from the second partially extended position shown in FIG. 4G to the extended position shown in FIG. 4H.

FIG. 4H shows the swapper 430 in an extended position such that the first arm 141 is disposed within the load lock 170 and the second arm 142 is positioned within the processing chamber 110. In other words, the first arm 141 and second arm 142 have swapped positions with the placement shown in FIG. 4A. The first arm 141 and second arm 142 may be returned to the extended position shown in FIG. 4A by reversing the movements of the swapper 430. The swapper 430 can move moved as described to swap substrates 105 disposed on the arms 141, 142 between the processing chamber 110 and the load lock 170.

In some embodiments, the swapper 430 is extended to place a substrate 105 into the processing chamber 110. After the substrate 105 is transferred to the lift pins of the substrate support 112, the swapper 430 may be moved to the retracted position to allow the slit valve 114 to close during processing.

The swapper 430 allows for center correction of the substrate 105 in both the X and Y directions in a similar manner as described with swapper 430 as the first and second motor 405 can be used to coordinate the position of the first and second arms 141, 142 to center an offset substrate disposed thereon over the center of either the load lock 170 or the center of the substrate support 112.

FIG. 5 illustrates a partial exploded view of a belt system 500 to show an in-line tensioner 510. The in-line tensioner 510 is connected to a first belt portion 501 and a second belt portion 502. The first and second belt portions 501, 502 may be part of a belt that loops around two pulleys, similar to belt 153 shown in FIG. 1B, or are part of a band that is anchored to two pulleys, such as band 251 shown in FIG. 2B. The in-line tensioner 510 allows the belt or band that it is connected to experience a desired tension. The tensioner 155 described herein may be the in-line tensioner 510.

The in-line tensioner 510 includes a block 520 and a biasing element 530. The block 520 includes a channel, such as a C-shaped channel shown in FIG. 5, running between both ends of the block 520. The block 520 also includes first block fastener openings 524 that are disposed within the channel 522. The biasing element 530 is disposed with in the channel 522.

The biasing element 530 includes a first portion 531, a second portion 532, and a third portion 533. The first portion 531 and second portion 532 may be rectangular elements as shown in FIG. 5. The third portion 533 is disposed between the first portion 531 and the second portion 532. Third portion 533 is a biasing member, such as a spring cut or machined into the biasing element 530. FIG. 5 shows the portion 533 including a plurality of spring slots 535 with the spring including a plurality of “U” shaped turns extending from the first portion 531 to the second portion 532. The spring slots 535 extend from a first side 536 of the biasing element 530 to a second side 537 of the biasing element 530. An upper surface 538 of the biasing element 530 is partially defined by the third portion 533, in that the upper surface 538 defines one or more of the spring slots 535. Similarly, a lower surface 539 of the biasing element 530 is partially defined by one or more of the spring slots 535. Thus, the third portion 533 may be a linear spring as shown in FIG. 5 rather than being a coiled spring. The third portion 533 is biased toward a neutral state, shown in FIG. 5, in that the third portion 533 will tend to pull the first belt portion 501 and the second belt portion 502 toward each other.

The first portion 531 and second portion 532 each include at least one belt fastener opening 534. The first belt portion 501 may be secured to the first portion 531 of the biasing element 530 by a belt fastener 540 inserted into an opening 503 in the first belt portion 501 and into the belt fastener opening 534 in the first portion 531. Similarly, the second belt portion 502 may be secured to the second portion 532 of the biasing element 530 by a belt fastener 540 inserted into an opening 503 in the second belt portion 502 and into the belt fastener opening 534 in the second portion 532. The belt fastener 540 may be a screw or a bolt.

The biasing element 530 further includes a slot 561 and at least one second block fastener opening 562. FIG. 5 shows the slot 561 formed in the first portion 531 and the second block fastener opening 562 formed in the second portion 532.

A block fastener 550 is inserted through the second block fastener opening 562 and into one of the first block fastener openings 524 to secure the first portion 531 of the biasing element 530 to the block 520. In other words, the second portion 532 of the biasing element 530 is held in a fixed position relative to the block 520 by the block fastener 550.

The slot 561 extends along the longitudinal axis of the biasing element 530 and further extends from the first side 536 to the second side 537. A block fastener 550 may be inserted into the slot 561 and into a first block fastener opening 524. The block fastener 550 may slide in the slot 561. Thus, the slot 561 allows the first portion 531 and the third portion to move relative to the block 520 and relative to the fixed second portion 532 when the block fastener 550 is inserted into the slot 561. In other words, the slot 561 allows the third portion 533 to apply tension to the belt by biasing the first belt portion 501 towards the second belt portion 502 that is fixed to the block 520.

While the foregoing is directed to embodiments of the present disclosure, other and further embodiments of the disclosure may be devised without departing from the basic scope thereof, and the scope thereof is determined by the claims that follow.

What is claimed is:

1. A swapper for a cluster tool, comprising:
a base including an interior chamber, wherein the base is rotatable about a central axis;
a pulley system at least partially disposed in the interior chamber, the pulley system including:
a multi-level central pulley, wherein the base is rotatable relative to the multi-level central pulley;
a first elbow pulley rotatable about a first elbow axis;
a second elbow pulley rotatable about a second elbow axis;
a first belt looping around a first level of the multi-level central pulley and the first elbow pulley; and
a second belt looping around a second level of the multi-level central pulley and the second elbow pulley; and
a first arm rotationally coupled to the first elbow pulley such that rotation of the first elbow pulley rotates the first arm about the first elbow axis; and
a second arm rotationally coupled to the second elbow pulley such that rotation of the second elbow pulley rotates the second arm about the second elbow axis.

2. The swapper of claim 1, wherein:
the base has a first distance between the central axis and the first elbow axis; and
the first arm has a second distance between a central point of a support of the first arm to the first elbow axis, wherein the first distance and the second distance are equivalent distances.

3. The swapper of claim 1, further comprising:
a motor assembly configured to rotate the base relative to the central pulley to move a center point of a support of the first arm and a center point of a support of the second arm along a linear trajectory.

4. The swapper of claim 1, wherein first belt and the second belt each include an in-line tensioner.

5. The swapper of claim 4, wherein at least one of the in-line tensioners includes:
a block including a channel, a first block opening, and a second block opening; and
a biasing element disposable in the channel, the biasing element including:
a first portion including a slot,
a second portion including a block fastener opening, and
a third portion disposed between the first portion and the second portion, the third portion including a plurality of spring slots, the third portion configured to bias the first portion towards the second portion.

6. A swapper for a cluster tool, comprising:
a base including an interior chamber, wherein the base is rotatable about a central axis;
a pulley system at least partially disposed in the interior chamber, the pulley system including:
a multi-level central pulley, wherein the base is rotatable relative to the multi-level central pulley;
a multi-level first elbow pulley rotatable about a first elbow axis;
a multi-level second elbow pulley rotatable about a second elbow axis;
a first band, wherein a first end of the first band is anchored to a first level of the multi-level central pulley and a second end of the first band is anchored to a first level of the first multi-level elbow pulley;
a second band, wherein a first end of the second band is anchored to the first level of the multi-level central pulley and a second end of the second band is anchored to a first level of the second multi-level elbow pulley;
a third band, wherein a first end of the third band is anchored to a second level of the multi-level central pulley and a second end of the third band is anchored to a second level of the first multi-level elbow pulley; and
a fourth band, wherein a first end of the fourth band is anchored to the second level of the multi-level central pulley and a second end of the fourth band is anchored to a second level of the second multi-level elbow pulley;
a first arm rotationally coupled to the first multi-leveled elbow pulley such that rotation of the first multi-leveled elbow pulley rotates the first arm about the first elbow axis; and
a second arm rotationally coupled to the second multi-leveled elbow pulley such that rotation of the second multi-leveled elbow pulley rotates the second arm about the second elbow axis.

7. The swapper of claim 6, wherein:
the base has a first distance between the central axis and the first elbow axis; and
the first arm has a second distance between a central point of a support of the first arm to the first elbow axis, wherein the first distance and the second distance are equivalent distances.

8. The swapper of claim 6, further comprising:
a motor assembly configured to rotate the base relative to the central pulley to move a center point of a support of the first arm and a center point of a support of the second arm along a linear trajectory.

9. The swapper of claim 6, wherein:
a central point of a support of the first arm is not linearly aligned with the first elbow axis and the central axis when the first arm is in an extended position.

10. The swapper of claim 6, wherein the first band, second band, third band, and fourth band each include an in-line tensioner.

11. The swapper of claim 10, wherein at least one of the in-line tensioners includes:
a block including a channel, a first block opening, and a second block opening; and
a biasing element disposable in the channel, the biasing element including:
a first portion including a slot,
a second portion including a block fastener opening, and
a third portion disposed between the first portion and the second portion, the third portion including a plurality of spring slots, the third portion configured to bias the first portion towards the second portion.

12. A swapper assembly for a cluster tool, comprising:
a housing including a first opening and a second opening;
a swapper, the swapper including:
a base rotatable relative to the housing about a central axis;
a first arm rotationally coupled to the base, wherein the first arm rotates relative to the base about a first elbow axis from a first retracted position to a first extended position, wherein the first arm is partially disposed in the first opening in the first extended position and the first elbow axis is disposed in the housing in the first extended position; and
a second arm rotationally coupled to the base, wherein the second arm rotates relative to the base about a second elbow axis from a second retracted position to a second extended position, wherein the second arm is partially disposed in the second opening in the second extended position and the second elbow axis is disposed in the housing in the second extended position.

13. The swapper assembly of claim 12, wherein:
the base has a first distance between the central axis and the first elbow axis; and
the first arm has a second distance between a central point of a support of the first arm to the first elbow axis, wherein the first distance and the second distance are different distances.

14. The swapper assembly of claim 12, further comprising:
a pulley system configured to move the first arm and the second arm.

15. The swapper assembly of claim 12, wherein:
the first arm is moveable from the retracted position to a partially extended position along a first trajectory, wherein a center point of a support of the first arm is disposed in the housing when the first arm is in the partially extended position.

16. The swapper assembly of claim 15, wherein the first trajectory is a linear trajectory.

17. The swapper assembly of claim 15, wherein:
the first arm is moveable from the partially extended position to the extended position along a second trajectory, wherein the center point passes through the first opening as the first arm moves along the second trajectory.

18. The swapper assembly of claim 12, further comprising:
a pulley system disposed in an interior chamber of the base, the pulley system including:
a central pulley rotatable relative to the base;
a first elbow pulley coupled to the first arm and rotatable about the first elbow axis;
a second elbow pulley coupled to the second arm and rotatable about the second elbow axis;
at least one of first belts or first bands extending between the first central pulley and the first elbow pulley to rotate the first elbow pulley, and therefore the first arm, about the first elbow axis in response to the rotation of the central pulley; and
at least one of second belts or second bands extending between the central pulley and the second elbow pulley to rotate the first elbow pulley, and therefore the second arm, about the second elbow axis in response to the rotation of the central pulley.

19. The swapper assembly of claim 18, wherein the first elbow pulley and the second elbow pulley each have a non-circular profile.

20. The swapper assembly of claim 18, further comprising:
a first motor configured to rotate a first shaft coupled to the base, wherein the rotation of the first shaft causes the base to rotate about the central axis; and
a second motor configured to rotate a second shaft coupled to the central pulley, wherein the rotation of the second shaft causes the central pulley to rotate about the central axis.
